(19) United States
(12) Patent Application Publication
(10) Pub. No.: US 2026/0150304 A1
(43) Pub. Date: May 28, 2026

(54) SEMICONDUCTOR DEVICES

(71) Applicant: Samsung Electronics Co., Ltd., Suwon-si (KR)

(72) Inventors: Yunjo Lee, Suwon-si (KR); Kang Lib Kim, Suwon-si (KR); Jemin Ahn, Suwon-si (KR); Gyeongsik Eom, Suwon-si (KR); Jaehooin Lee, Suwon-si (KR); Dongjin Lee, Suwon-si (KR); Jaeduk Lee, Suwon-si (KR)

(21) Appl. No.: 19/222,250

(22) Filed: May 29, 2025

(30) Foreign Application Priority Data
Nov. 28, 2024 (KR) 10-2024-0173776

(51) Int. Cl. H10B 80/00; H01L 23/00; H01L 25/00; H01L 25/065; H01L 25/18; H10B 41/41; H10B 43/40

(52) U.S. Cl. CPC H10B 80/00; H10B 41/41; H10B 43/40; H10W 90/00; H10W 80/312; H10W 80/327; H10W 90/297; H10W 90/792

(57) ABSTRACT

A semiconductor device includes: a first peripheral circuit structure including a first substrate having a first thickness, and first transistors that are configured to operate at a first voltage; a second peripheral circuit structure on the first peripheral circuit structure, and including a second substrate of a first conductivity type having a second thickness that is equal to or less than the first thickness, second transistors that are configured to operate at a second voltage that is greater than the first voltage, on a front surface of the second substrate, and a rear doping layer including impurities of the first conductivity type on a rear surface of the second substrate; and a cell structure electrically connected to the second peripheral circuit structure, and including gate electrodes and channel structures extending into the gate electrodes in a vertical direction.

### CROSS-REFERENCE TO RELATED APPLICATIONS

This application claims benefit of priority to Korean Patent Application No. 10-2024-0173776 filed on Nov. 28, 2024, in the Korean Intellectual Property Office, the disclosure of which is incorporated herein by reference in its entirety.

### BACKGROUND OF THE INVENTION

The present disclosure relates to semiconductor devices and data storage systems including the same.

In a data storage system requiring data storage, a semiconductor device capable of storing (a large amount of) data may be needed. Accordingly, a method of increasing the data storage capacity of a semiconductor device has been researched. For example, as one method of increasing the data storage capacity of a semiconductor device, a semiconductor device including memory cells arranged three-dimensionally, instead of memory cells arranged two-dimensionally, has been proposed. Additionally, circuit elements driving the memory cells may include complementary metal-oxide-semiconductor (CMOS) transistors.

### SUMMARY OF THE INVENTION

An aspect of the present disclosure is to miniaturize and thin a semiconductor substrate of a peripheral circuit structure driven by a high voltage, among peripheral circuit structures driving a cell structure, so that the semiconductor substrate has a small thickness.

An aspect of the present disclosure is to provide a semiconductor device reducing (e.g., preventing) the diffusion of a depletion region of well-less transistor elements, and applying impurity doping to a rear surface of a semiconductor substrate to reduce (e.g., prevent) leakage current caused by positive charges generated on the rear surface of the semiconductor substrate due to thinning.

A semiconductor device according to example embodiments includes: a first peripheral circuit structure that includes a first substrate having a first thickness, a first peripheral circuit including a first gate stack on the first substrate, and first peripheral interconnection lines electrically connected to the first peripheral circuit; a second peripheral circuit structure that includes a second substrate of a first conductivity type and having a second thickness that is equal to or less than the first thickness, second peripheral circuits each including a second gate stack on a front surface of the second substrate, second peripheral interconnection lines electrically connected to the second peripheral circuits, peripheral bonding pads electrically connected to the second peripheral interconnection lines, and a rear doping layer including impurities of the first conductivity type and is on a rear surface of the second substrate, wherein the rear surface is opposite to the front surface in a vertical direction and faces the first peripheral circuit structure, and wherein the vertical direction is perpendicular to the rear surface and/or the front surface; and a cell structure including a source structure, gate electrodes on the source structure, channel structures extending into the gate electrodes in the vertical direction, cell interconnection lines electrically connected to the gate electrodes and the channel structures, and cell bonding pads electrically connected to the cell interconnection lines, wherein the cell structure faces the front surface, and wherein the cell bonding pads are in contact with the peripheral bonding pads.

A semiconductor device according to example embodiments includes: a first peripheral circuit structure including a first substrate having a first thickness, and first transistors that are configured to operate at an operating voltage of a first voltage; a second peripheral circuit structure on the first peripheral circuit structure, and including a second substrate of a first conductivity type having a second thickness that is equal to or less than the first thickness, second transistors that are configured to operate at an operating voltage of a second voltage that is greater than the first voltage, on a front surface of the second substrate, and a rear doping layer including impurities of the first conductivity type on a rear surface of the second substrate, wherein the rear surface is opposite to the front surface in a vertical direction that is perpendicular to the rear surface and/or the front surface; and a cell structure electrically connected to the second peripheral circuit structure, and including gate electrodes and channel structures extending into the gate electrodes in the vertical direction.

A semiconductor device according to example embodiments includes: a first peripheral circuit structure on a first substrate having a first thickness, and including a page buffer and a row decoder configured to operate at an operating voltage of a first voltage; a second peripheral circuit structure including a second substrate having a front surface and a rear surface, the rear surface facing the first peripheral circuit structure, and having a second thickness, equal to or less than the first thickness, a pass circuit configured to operate at an operating voltage of a second voltage that is greater than the first voltage, and a common source line driver configured to operate at an operating voltage of a third voltage that is greater than the second voltage, and a rear doping layer including impurities of a same conductivity type as the second substrate on the rear surface of the second substrate; and a cell structure electrically connected to the second peripheral circuit structure, and including a channel structure extending into gate electrodes.

A first peripheral circuit structure, a second peripheral circuit structure and a cell structure, which are sequentially disposed, may be included, and the first peripheral circuit having a low operating voltage may be disposed in the first peripheral circuit structure, and the second peripheral circuit having a high operating voltage may be disposed in the second peripheral circuit structure, thereby improving the integration of a semiconductor device, and electrical paths between peripheral circuits may be efficiently disposed, thereby improving the performance of the semiconductor device. The semiconductor substrate of the second peripheral circuit structure may be made thinner to have a significantly small thickness, thereby further miniaturizing the semiconductor device.

By applying impurities doping layer to a rear surface of the semiconductor substrate, a depletion region of well-less transistor elements may be limited (e.g., prevented) from extending to the rear surface of the semiconductor substrate, and leakage current caused by positive charges generated on the rear surface of the semiconductor substrate during the thinning process may be reduced (e.g., prevented), thereby ensuring reliability thereof.

Advantages and effects of the present application are not limited to the foregoing content and may be easily understood in the process of describing a specific example embodiment of the present disclosure.

### BRIEF DESCRIPTION OF DRAWINGS

The above and other aspects, features, and advantages of the present disclosure will be clearly understood from the following detailed description, taken in conjunction with the accompanying drawings, in which:

FIG. 1A is a block diagram of a semiconductor device according to example embodiments of the present disclosure;

FIG. 1B is a block diagram illustrating a schematic connection relationship between a cell structure of a semiconductor device and first and second peripheral circuit structures according to example embodiments of the present disclosure;

FIG. 1C is an equivalent circuit diagram of a memory cell array of FIG. 1A according to example embodiments;

FIG. 2 is a schematic perspective view of a semiconductor device according to example embodiments;

FIG. 3A is a circuit diagram illustrating a mat structure of the cell structure of FIG. 2 according to example embodiments;

FIGS. 3B and 3C are plan views of the first and second peripheral circuit structures of FIG. 2, respectively, according to example embodiments;

FIG. 4 is a cross-sectional view of the semiconductor device of FIG. 2 according to example embodiments;

FIGS. 5A, 5B, 5C, 5D, and 5E are partially enlarged views according to example embodiments of FIG. 4;

FIGS. 6A and 6B are partially enlarged views according to example embodiments of FIG. 4;

FIG. 7A is a schematic perspective view of a semiconductor device according to example embodiments;

FIG. 7B is a cross-sectional view of the semiconductor device of FIG. 7A;

FIGS. 8 and 9 are cross-sectional views of a semiconductor device according to example embodiments;

FIGS. 10A, 10B, 10C, 10D, 10E, 10F, 10G, 10H, and 10I are views illustrating a method of manufacturing the semiconductor device of FIG. 4 according to example embodiments;

FIG. 11 is a view schematically illustrating a data storage system including a semiconductor device according to example embodiments of the present disclosure; and

FIG. 12 is a perspective view schematically illustrating a data storage system including a semiconductor device according to example embodiments of the present disclosure.

### DETAILED DESCRIPTION

Hereinafter, example embodiments of the present disclosure will be described with reference to the accompanying drawings.

Hereinafter, example embodiments of the present disclosure will be described with reference to the accompanying drawings. Hereinafter, spatially relative terms such as “on,” “above,” “upper,” “upper portion,” “upper surface,” “below,” “lower,” “lower portion,” “lower surface,” “side surface,” and the like may be denoted by reference numerals and refer to the drawings, except where otherwise indicated. Herein, the terms indicating order, such as first, second, etc., are used to distinguish elements having the same/similar functions, and the ordinal numbers may be interchanged according to the order in which the terms are mentioned. To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

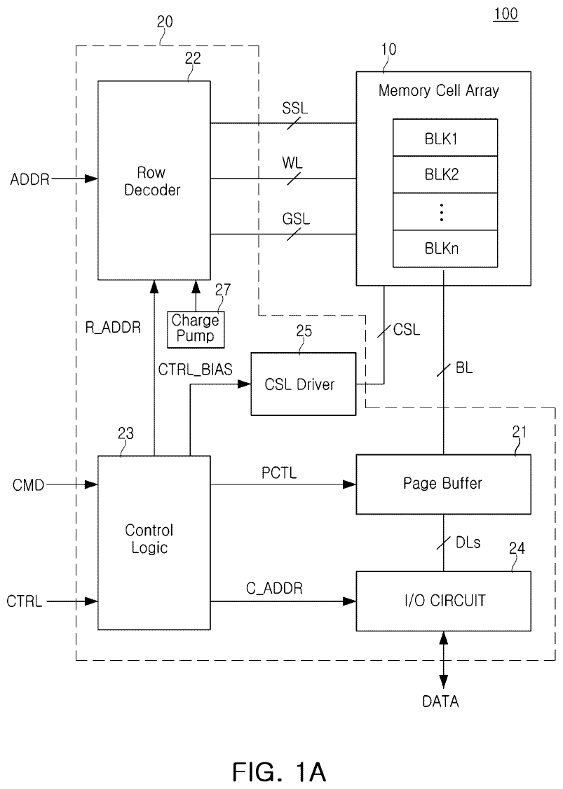

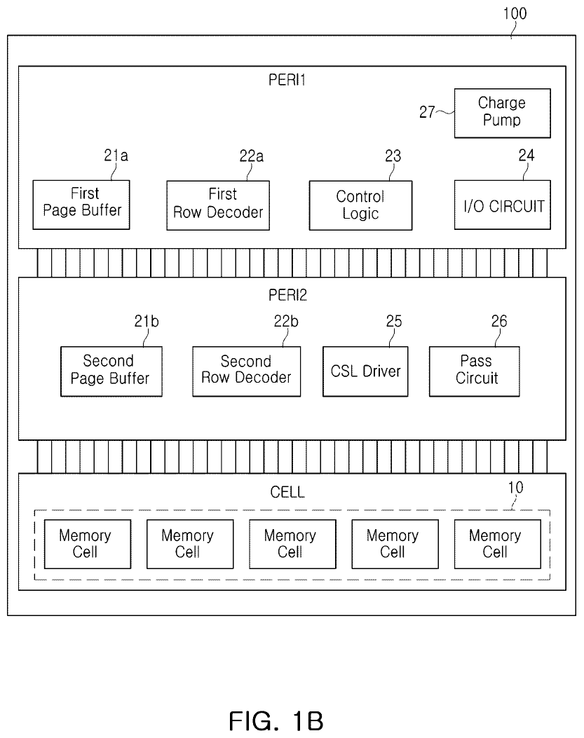

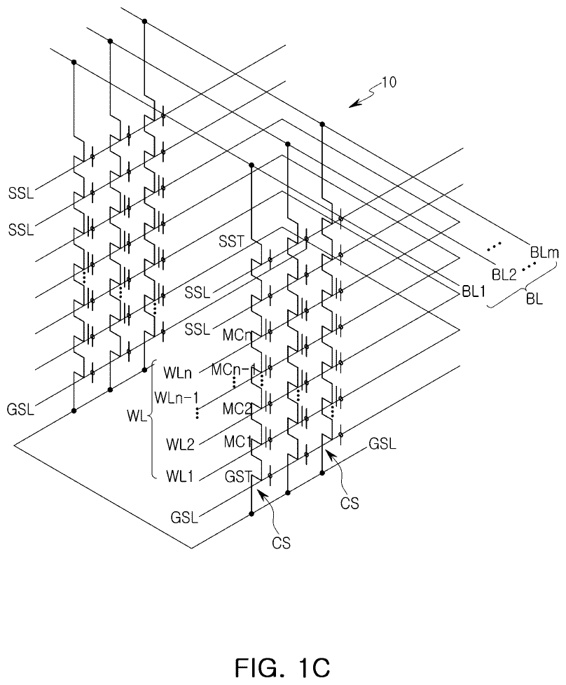

FIG. 1A is a block diagram of a semiconductor device according to example embodiments of the present disclosure. FIG. 1B is a block diagram illustrating a schematic connection relationship between a cell structure of a semiconductor device and first and second peripheral circuit structures according to example embodiments of the present disclosure.

Referring to FIG. 1A, a semiconductor device 100 may include a memory cell array 10 and a peripheral circuit 20. The memory cell array 10 may include a plurality of memory cell blocks (BLK1, BLK2, . . . , BLKn). The plurality of memory cell blocks (BLK1, BLK2, . . . , BLKn) may be electrically connected to the peripheral circuit 20 through a bit line BL, a word line WL, a string select line SSL, and a ground select line GSL.

The peripheral circuit 20 may include a page buffer 21, a row decoder 22, a control logic 23, an input/output circuit 24, and a common source line driver 25. Although not illustrated in FIG. 1A, the peripheral circuit 20 may further include various circuits such as a voltage generation circuit (or voltage generator) generating various voltages required for the operation of the semiconductor device 100, a circuit for storing data read from the memory cell array 10, and an input/output interface.

The memory cell array 10 may be electrically connected to the page buffer 21 through the bit line BL, and may be electrically connected to the row decoder 22 through the word line WL, the string select line SSL and the ground select line GSL. Each of the plurality of memory cells included in the plurality of memory cell blocks (BLK1, BLK2, . . . , BLKn) of the memory cell array 10 may be a flash memory cell. The memory cell array 10 may include a three-dimensional memory cell array. The three-dimensional memory cell array may include a plurality of NAND strings, and each of the plurality of NAND strings may include a plurality of memory cells (electrically) connected to a plurality of word lines WL that are vertically stacked.

The peripheral circuit 20 may receive an address ADDR, a command CMD, and a control signal CTRL from the outside of the semiconductor device 100, and may transmit or receive data DATA to or from an external device located outside the semiconductor device 100. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

The page buffer 21 may be electrically connected to the memory cell array 10 via the bit line BL. The page buffer 21 may operate as a write driver during a program operation to apply a voltage according to data DATA to be stored in the memory cell array 10 to the bit line BL, and may operate as a sense amplifier during a read operation to detect data DATA stored in the memory cell array 10. The page buffer 21 may operate according to a control signal CTRL provided from the control logic 23.

The row decoder 22 may select at least one of the plurality of cell blocks (BLK1, BLK2, . . . , BLKn) in response to the address ADDR from the outside, and may select the word line WL, the string select line SSL and the ground select line GSL of the selected memory cell block. The row decoder 22 may transmit a voltage for performing a memory operation to the word line WL of the selected memory cell block.

The input/output circuit 24 may be (electrically) connected to the page buffer 21 through a plurality of data lines DL. The input/output circuit 24 may receive data DATA from a memory controller (not illustrated) during the program operation, and may provide program data DATA to the page buffer 21 based on a column address C_ADDR provided from the control logic 23. The input/output circuit 24 may provide the read data DATA stored in the page buffer 21 to the memory controller based on the column address C_ADDR provided from the control logic 23 during the read operation.

The input/output circuit 24 may transmit the input address or command to the control logic 23 or the row decoder 22. The peripheral circuit 20 may further include an electro static discharge (ESD) circuit and a pull-up/pull-down circuit.

The control logic 23 may receive the command CMD and the control signal CTRL from the memory controller. The control logic 23 may provide a row address R_ADDR to the row decoder 22, and may provide the column address C_ADDR to the input/output circuit 24. The control logic 23 may generate various internal control signals used in the semiconductor device 100 in response to the control signal CTRL. For example, the control logic 23 may adjust a voltage level provided to the word line WL and the bit line BL when performing a memory operation such as a program operation or an erase operation.

The common source line driver 25 may be electrically connected to the memory cell array 10 through a common source line CSL. The common source line driver 25 may apply a common source voltage (e.g., a power voltage) or a ground voltage to the common source line CSL based on the control of the control logic 23.

A charge pump 27 may generate various types of internal voltages for performing program read and erase operations for the memory cell array 10 based on the control signal received from the control logic 23.

In one example, the peripheral circuit 20 may include a plurality of MOS transistors, and the plurality of MOS transistors may be classified according to the size of operating voltages thereof and may be distributed and arranged in a plurality of transistor regions. For example, the peripheral circuit 20 may include a first peripheral circuit region (e.g., a first peripheral circuit structure PERI1 of FIG. 1B) in which a plurality of low-voltage MOS transistors (e.g., MOS transistors having an operating voltage(s) lower than a plurality of high-voltage MOS transistors in a second peripheral circuit region) are formed, and a second peripheral circuit region (e.g., a second peripheral circuit structure PERI2 of FIG. 1B) in which a plurality of high-voltage MOS transistors (e.g., MOS transistors having an operating voltage(s) higher than the plurality of lower-voltage MOS transistors in the first peripheral circuit region) are formed. Additionally, the peripheral circuit 20 may include various regions in which intermediate-voltage MOS transistors are disposed, which have an operating voltage that is higher than an operating voltage of the low-voltage MOS transistors disposed in the first peripheral circuit region, and lower than an operating voltage of the high-voltage MOS transistors disposed in the second peripheral circuit region.

Referring to FIG. 1B, the semiconductor device 100 may include a cell structure CELL, a first peripheral circuit structure PERI1, and a second peripheral circuit structure PERI2.

The cell structure CELL may include a memory cell array 10 as a storage region. The first and second peripheral circuit structures PERI1 and PERI2 may include a peripheral circuit 20 as a peri region.

The first peripheral circuit structure PERI1 may include a plurality of low-voltage MOS transistors, and the second peripheral circuit structure PERI2 may include a plurality of high-voltage MOS transistors.

The first peripheral circuit structure PERI1 may include a first page buffer 21a, a first row decoder 22a, a control logic 23, an input/output circuit 24 and a charge pump 27, which have a relatively low level (low voltage) of operating voltage. The relatively low level of operating voltage may refer to a lower voltage than a reference voltage. For example, an operating voltage of at least one of the plurality of low-voltage MOS transistors in the first peripheral circuit structure PERI1 may be less (lower) than an operating voltage of at least one of the plurality of high-voltage MOS transistors in the second peripheral circuit structure PERI2.

The second peripheral circuit structure PERI2 may include a second page buffer 21b, a second row decoder 22b, a common source line driver 25 and a pass circuit 26, which have a relatively high level (high voltage) of operating voltage. The relatively high level of operating voltage may refer to a higher voltage than a reference voltage. For example, an operating voltage of at least one of the plurality of high-voltage MOS transistors in the second peripheral circuit structure PERI2 may be greater (higher) than an operating voltage of at least one of the plurality of low-voltage MOS transistors in the first peripheral circuit structure PERI1.

The page buffer 21 may include a plurality of page buffers 21a and 21b (electrically) connected to the bit line BL. The plurality of page buffers 21a and 21b may include the second page buffer 21b (electrically) connected to the bit line BL and the first page buffer 21a (electrically) connected to the second page buffer 21b.

The first page buffer 21a may be disposed in the first peripheral circuit structure PERI1. The second page buffer 21b may be disposed in the second peripheral circuit structure PERI2. In one example, the first page buffer 21a may have a relatively low level of operating voltage (e.g., a lower operating voltage than the second page buffer 21b), and the second page buffer 21b may have a relatively high level of operating voltage (e.g., a higher operating voltage than the first page buffer 21a).

The pass circuit 26 may control a low line voltage applied from the charge pump 27 to the string select line SSL, the word line WL, and the ground select line GSL. The pass circuit 26 may be disposed in the second peripheral circuit structure PERI2.

The pass circuit 26 may include a plurality of pass transistors. The low line voltage applied to the ground select line GSL, the word line WL, the ground select line GSL may be controlled based on switching operations of the plurality of pass transistors.

The row decoder 22 may include a block selector and drivers for the string selector line SSL, the word line WL and the ground selector line GSL. The row decoder 22 (e.g., the block selector) may select at least one of the plurality of cell blocks (BLK1, BLK2, . . . , BLKn) in response to the address ADDR from the outside. The row decoder 22 (e.g., drivers of the string selector line SSL, the word line WL and the ground selector line GSL) may select the word line WL, the string selector line SSL and the ground selector line GSL of the selected memory cell block (of the plurality of memory cell block BLK1, BLK2, . . . , BLKn). The row decoder 22 (e.g., a driver of the string selector line SSL) may be (electrically) connected to the string selector line SSL through the pass circuit 26 and may drive the string selector line SSL. For example, during an erase operation, the row decoder 22 may float the string select line SSL, and during a program operation, the row decoder 22 may provide a string select voltage (e.g., power voltage) to the string select line SSL. The row decoder 22 (e.g., a driver of the word line WL) may be (electrically) connected to the word line WL through the pass circuit 26 and may drive the word line WL. For example, during the erase operation, an erase voltage may be applied to a bulk in which the plurality of cell blocks (BLK1, BLK2, . . . , BLKn) are formed, and a relatively low level of word line voltage (e.g., ground voltage) may be applied to the word line WL. Additionally, during the program operation, a program voltage may be provided to a selected word line and a pass voltage may be provided to an unselected word line. The row decoder 22 (a driver of the ground select line GSL) may drive the ground select line GSL through the pass circuit 26. For example, during the erase operation, the row decoder 22 may float the ground select line GSL, and during a program operation, the row decoder 22 may provide a relatively low level of ground selection voltage (e.g., ground voltage) to the ground select line GSL.

The row decoder 22 may include a first row decoder 22a having a relatively low level (low voltage) of operating voltage (e.g., a lower operating voltage than a second row decoder 22b) and a second row decoder 22b having a high level (high voltage) of operating voltage (e.g., a higher operating voltage than the first row decoder 22a). For example, the first row decoder 22a may provide a low level of ground voltage to the word line WL and/or the ground select line GSL, and the second row decoder 22b may provide a high level of power voltage to the string select line SSL.

The first row decoder 22a may be disposed in the first peripheral circuit structure PERI1, and the second row decoder 22b may be arranged in the second peripheral circuit structure PERI2.

The control logic 23 may include elements for controlling an overall operation of reading data from the memory cell array 10 or recording data in the memory cell array 10.

Although not illustrated in FIG. 1B, the first peripheral circuit structure PERI1 may further include a scheduler. The scheduler may perform scheduling for a plurality of operations simultaneously requested for the memory cell array 10. For example, the scheduler may control to reduce the number of requests when the number of concurrently requested recording and reading requests exceeds a threshold criterion, and may change an operation order to delay garbage collection after a plurality of recording requests and process reading requests first. In one example, the scheduler may be included in the control logic 23 or disposed as an independent circuit.

FIG. 1C is an equivalent circuit diagram of the memory cell array of FIG. 1A according to example embodiments.

FIG. 1C illustrates an example embodiment of an equivalent circuit diagram of a vertical NAND flash memory device having a vertical channel structure. The plurality of memory cell blocks (BLK1, BLK2, . . . , BLKn) of FIG. 1A may have a circuit configuration illustrated in FIG. 1C.

Referring to FIG. 1C, the memory cell array 10 may include a plurality of cell strings CS. The memory cell array 10 may include a plurality of bit lines BL (BL1, BL2, . . . , BLm), a plurality of word lines WL (WL1, WL2, . . . , WLn), at least one string select line SSL, at least one ground select line GSL, and a common source line CSL. In FIG. 1C, each of the plurality of cell strings CS are illustrated as including one ground select line GSL and two string select lines SSL, but the present disclosure is not limited thereto. For example, each of the plurality of cell strings CS may include one string select line SSL.

In the plurality of cell strings CS, a string select transistor SST, a ground select transistor GST and a plurality of memory cell transistors (MC1, MC2, . . . , MCn) may be (electrically) connected to a word line WL, respectively.

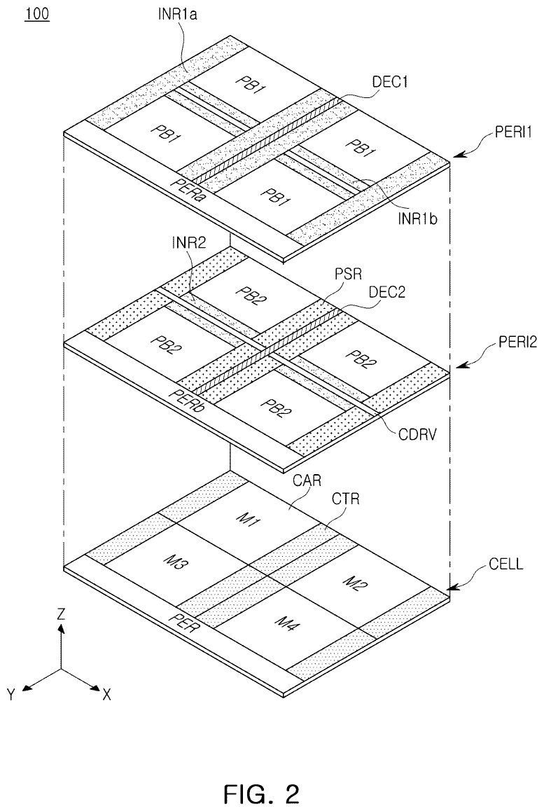

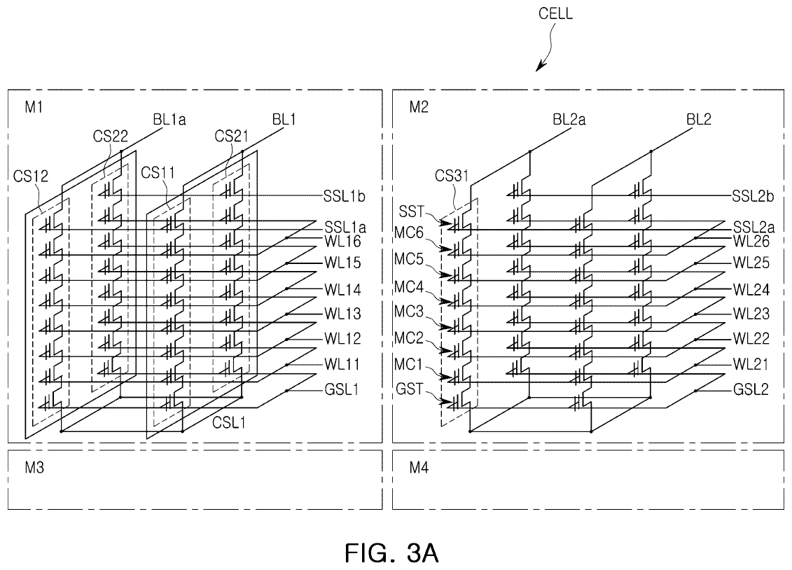

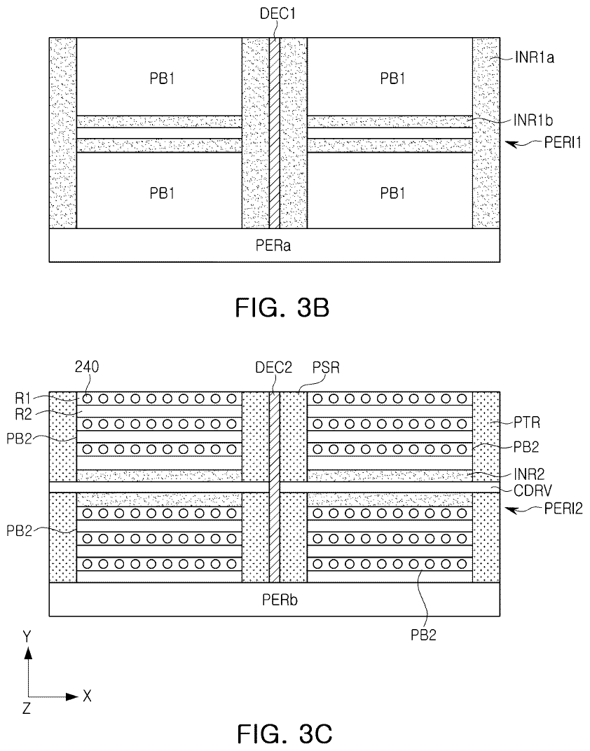

FIG. 2 is a schematic perspective view of a semiconductor device according to example embodiments. FIG. 3A is a circuit diagram illustrating a mat structure of the cell structure of FIG. 2 according to example embodiments. FIGS. 3B and 3C are plan views of the first peripheral circuit structure and the second peripheral circuit structure of FIG. 2, respectively, according to example embodiments.

Referring to FIG. 2, the semiconductor device 100 may include a cell structure CELL, a second peripheral circuit structure PERI2, and a first peripheral circuit structure PERI1, which are sequentially stacked in a vertical direction (e.g., Z-direction).

Referring to FIGS. 2 and 3A, the semiconductor device 100 may include a plurality of mats M1, M2, M3 and M4. In one example, the cell structure CELL may include a cell array region CAR and a cell contact region CTR for each of the plurality of mats M1, M2, M3 and M4.

The cell array region CAR may form a memory cell array (e.g., the memory cell array 10 of FIG. 1) including a plurality of memory cells. For example, a channel structure CH, bit lines BL, and gate electrodes (e.g., GSL, WL, SSL, and the like) described below may be disposed in the cell array region CAR. The cell contact region CTR may be disposed adjacent (around) the cell array region CAR. The gate electrodes (e.g., GSL, WL, SSL, and the like) may be stacked in a stepwise manner in the cell contact region CTR.

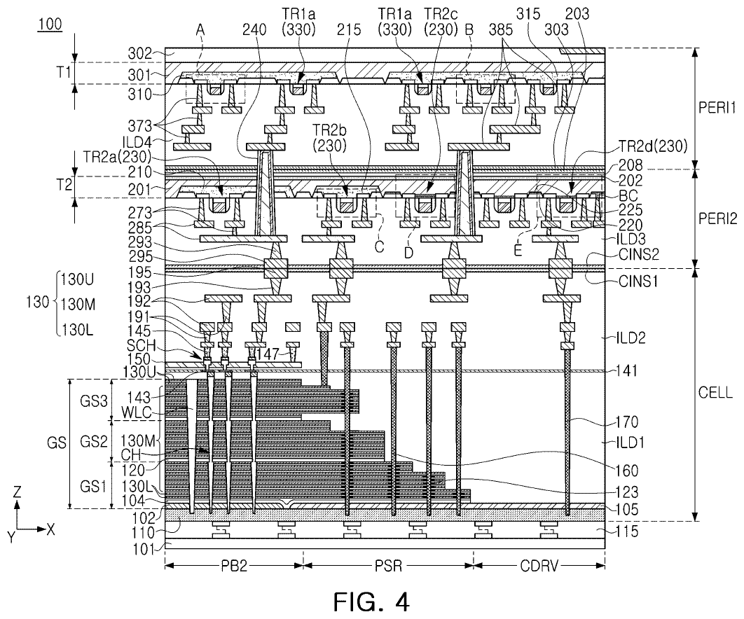

The cell structure CELL may further include a pad region PER (or a peri region). The pad region PER may be disposed outside the cell array region CAR and the cell contact region CTR. For example, the pad region PER may be adjacent the cell array region CAR and the cell contact region CTR. The pad region PER may not overlap the cell array region CAR or the cell contact region CTR in the vertical direction. A source contact plug (e.g., a source contact 170 of FIG. 4) and an input/output contact plug, which will be described below, may be disposed in the pad region PER.

The cell structure CELL may include a plurality of memory blocks (e.g., the plurality of memory blocks (BLK1, BLK2, . . . , BLKn) in FIG. 1) for each of the plurality of mats M1, M2, M3 and M4. Each of the plurality of memory blocks may include a plurality of cell strings. For example, one of the memory blocks included in the first mat M1 may include a plurality of cell strings CS11, CS12, CS21 and CS22. The plurality of cell strings included in one mat may be formed on a plurality of planes. In FIG. 3A, only the structure of the first and second mats M1 and M2 is illustrated, but the third and fourth mats M3 and M4 may have (substantially) the same structure as the first and second mats M1 and M2.

The first and second mats M1 and M2 of the cell structure CELL may include a plurality of memory blocks, and one of the plurality of memory blocks may include a plurality of string select lines SSL1a and SSL1b for selecting at least one cell string among the plurality of cell strings CS11, CS12, CS21 and CS22. For example, when a string selection voltage is applied to the first string select line SSL1a, the cell strings CS11 and CS12 may be selected. When a string selection voltage is applied to the second string select line SSL1b, the third and fourth cell strings CS21 and CS22 may be selected.

The first and second mats M1 and M2 may have (substantially) the same structure. For example, the cell strings (e.g., the plurality of cell strings CS11, CS12, CS21 and CS22) included in the first mat M1 may be (electrically) connected to word lines WL11 to WL16, a ground select line GSL1 and a common source line CSL1. The cell strings included in the second mat M2 may be (electrically) connected to word lines WL21 to WL26, a ground select line GSL2, and a common source line CSL2. The first and second mats M1 and M2 do not share bit lines. The first bit lines BL1 and BL1a may be exclusively (and electrically) connected to the first mat M1. The second bit lines BL2 and BL2a may be exclusively (and electrically) connected to the second mat M2. In FIG. 3A, it is assumed that each of the plurality of mats M1, M2, M3 and M4 is (electrically) connected to two bit lines and six word lines, but the present disclosure is not limited thereto, and each of the plurality of mats M1, M2, M3 and M4 may be (electrically) connected to three or more bit lines and seven or more word lines.

Each of the cell strings CS may include at least one string select transistor SST, a plurality of memory cell transistors MC1 to MC6, and a ground select transistor GST. For example, one cell string CS31 may have the ground select transistor GST, the plurality of memory cell transistors MC1 to MC6, and the string select transistor SST formed vertically on a substrate. The remaining cell strings (e.g., the cell strings CS in the second mat M2) may have (substantially) the same configuration as the cell string CS31.

Each of the string select lines SSL1a and SSL1b may be (electrically) connected only to the first mat M1. Each of the string select lines SSL2a and SSL2b may be (electrically) connected only to the second mat M2. The plurality of mats M1, M2, M3 and M4 may independently control respective string select interconnection lines, so that the cell strings may be independently selected for each of the plurality of mats M1, M2, M3 and M4. For example, a string selection voltage may be independently applied to the first string select line SSL1a, thus independently selecting the cell strings CS11 and CS12. When the string selection voltage is applied to the first string select line SSL1a, the string selection voltage may turn on a string select transistor (the string select transistor SST) of the corresponding cell strings CS11 and CS12. When the string select transistor SST is turned on, the memory cells of the cell strings CS11 and CS12 and bit lines may be electrically connected. Conversely, when a non-selection voltage is applied to the first string select line SSL1a, the string select transistors (the string select transistor SST) of the cell strings CS11 and CS12 may be turned off, and the cell strings CS11 and CS12 may be not selected. The memory cells of the cell strings CS11 and CS12 may be electrically disconnected from the first bit line BL1 (the first bit lines BL1 and BL1a).

Referring to FIGS. 2, 3B, and 3C, the first and second peripheral circuit structures PERI1 and PERI2 may include page buffer regions PB1 and PB2 corresponding to one region of the cell array region CAR of the cell structure CELL. The first peripheral circuit structure PERI1 may include first page buffer regions PB1 for each of the plurality of mats M1, M2, M3 and M4. The second peripheral circuit structure PERI2 may include second page buffer regions PB2 for each of the plurality of mats M1, M2, M3 and M4. In one example, the first page buffer regions PB1 and the second page buffer regions PB2 may overlap in the vertical direction (e.g., Z-direction). In one example, the first page buffer region PB1 of (corresponding to) the first mat M1 may overlap the second page buffer region PB2 of (corresponding to) the first mat M1 in the vertical direction.

A first page buffer (e.g., a first page buffer 21a of FIG. 1B) may be disposed in the first page buffer regions PB1. A second page buffer (e.g., a second page buffer 21b of FIG. 1B) may be disposed in the second page buffer regions PB2.

In the second page buffer region PB2, a first region R1 electrically connected to the first page buffer region PB1 and a second region R2 in which a second page buffer 21b is disposed may be alternately arranged in a second (horizontal) direction (e.g., Y-direction). The first region R1 and the second region R2 may not overlap each other in the vertical direction (e.g., Z-direction).

The first page buffer 21a may be electrically connected to the second page buffer 21b through a through-via 240 disposed in the first region R1 (also referred to as the connection region R1).

The second peripheral circuit structure PERI2 may include a pass circuit region PSR corresponding to one region of the cell contact region CTR. A pass circuit (e.g., a pass circuit 26 (see FIG. 1B)) may be disposed in the pass circuit region PSR. The pass circuit region PSR may not overlap the cell array region CAR and the first and second page buffer regions PB1 and PB2 (in the vertical direction). In one example, the pass circuit region PSR may be disposed on both sides (e.g., opposite sides) of the second page buffer region PB2.

The first and second peripheral circuit structures PERI1 and PERI2 may include row decoder regions DEC1 and DEC2, respectively, corresponding to boundary regions of the plurality of mats M1, M2, M3 and M4. In one example, the row decoder regions DEC1 and DEC2 may extend in the second (horizontal) direction (e.g., Y-direction) between the first mat M1 and the second mat M2 (in a first (horizontal) direction (e.g., X-direction)) and between the third mat M3 and the fourth mat M4 (in the first (horizontal) direction (e.g., X-direction)).

The first peripheral circuit structure PERI1 may include a first row decoder region DEC1, and the second peripheral circuit structure PERI2 may include a second row decoder region DEC2 overlapping the first row decoder region DEC1 (in the vertical direction).

A first row decoder (e.g., the first row decoder 22a of FIG. 1B) may be disposed in the first row decoder region DEC1. A second row decoder (e.g., the second row decoder 22b of FIG. 1B) may be disposed in the second row decoder region DEC2.

The second peripheral circuit structure PERI2 may include a common source line driving region CDRV corresponding to a boundary region of the plurality of mats M1, M2, M3 and M4. In one example, the common source line drive region CDRV may extend in a first (horizontal) direction (e.g., X-direction) between the first mat M1 and the third mat M3 and between the second mat M2 and the fourth mat M4. The common source drive region CDRV may include a region extending in the first (horizontal) direction (e.g., X-direction) between the first mat M1 and the third mat M3 and a region extending in the first (horizontal) direction (e.g., X-direction) between the second mat M2 and the fourth mat M4.

A common source line driver (e.g., the common source line driver 25 of FIG. 1B) may be disposed in the common source line drive region CDRV.

The second peripheral circuit structure PERI2 may include a second inner peri region INR2 between the common source line drive region CDRV and the second page buffer region PB2 (in the second horizontal direction (e.g., Y-direction)). The second inner peri region INR2 may be (at least partially) surrounded by the second page buffer region PB2, the pass circuit region PSR and the common source line driving region CDRV (in a plan view). In one example, the second page buffer region PB2 and the second inner peri region INR2 may overlap the cell array region CAR (in the vertical direction (e.g., Z-direction)).

A portion of the charge pump 27 of a voltage generator may be disposed in the second inner peri region INR2.

The first peripheral circuit structure PERI1 may include a first-first inner peri region INR1a corresponding to one region of the cell contact region CTR and overlapping the pass circuit region PSR (in the vertical direction (e.g., Z-direction)). The first-first inner peri region INR1a may not overlap the cell array region CAR and the first and second page buffer regions PB1 and PB2 (in the vertical direction (e.g., Z-direction)). In one example, the first-first inner peri region INR1a may be disposed on both sides (e.g., opposite sides in the first horizontal direction (e.g., X-direction)) of the first page buffer region PB1. The first-first inner peri region INR1a may be disposed between the first row decoder region DEC1 and the first page buffer region PB1 (in the first horizontal direction (e.g., X-direction)).

The first peripheral circuit structure PERI1 may include a first-second inner peri region INR1b overlapping the second inner peri region INR2 (in the vertical direction). In one example, the first page buffer region PB1 and the first-second inner peri region INR1b may overlap the cell array region CAR (in the vertical direction).

A control logic (e.g., control logic 23 of FIG. 1B) may be disposed in the first-first inner peri region INR1a and the first-second inner peri region INR1b. For example, a scheduler (not illustrated) may be disposed in the first-first inner peri region INR1a and the first-second inner peri region INR1b.

The first and second peripheral circuit structures PERI1 and PERI2 may include pad regions PERa and PERb, respectively, overlapping the pad region PER (in the vertical direction). The pad regions PERa and PERb may be disposed on one side of the plurality of mats M1, M2, M3 and M4. The first peripheral circuit structure PERI1 may include a first pad region PERa overlapping the pad region PER (in the vertical direction). The second peripheral circuit structure PERI2 may include a second pad region PERb overlapping the first pad region PERa (in the vertical direction).

An input/output circuit (e.g., an input/output circuit 24 of FIG. 1B) may be disposed in the first pad region PERa.

According to example embodiments of the present disclosure, a semiconductor device 100 may improve integration and signal speed by disposing a peripheral circuit of a small voltage (low voltage (lower voltage)) in the first peripheral circuit structure PERI1 and disposing a peripheral circuit of a large voltage (high voltage (higher voltage)) in the second peripheral circuit structure PERI2 adjacent to a cell structure CELL, according to the magnitude of the operating voltage of the peripheral circuits.

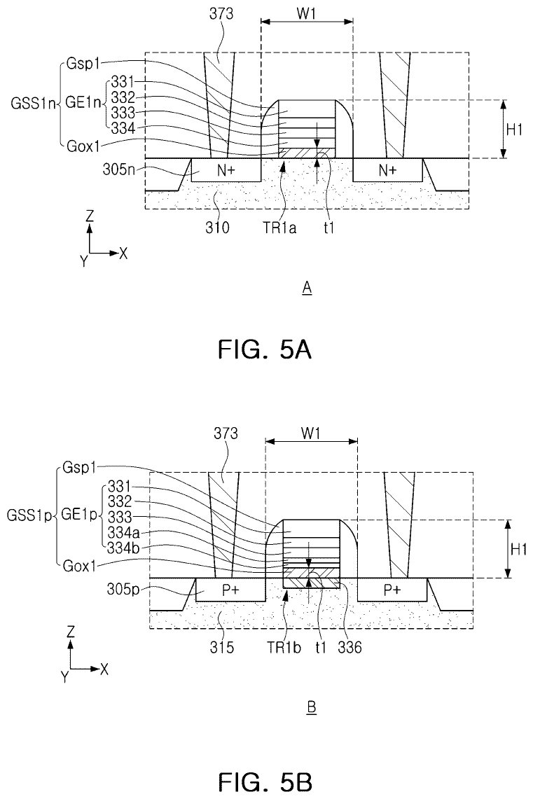

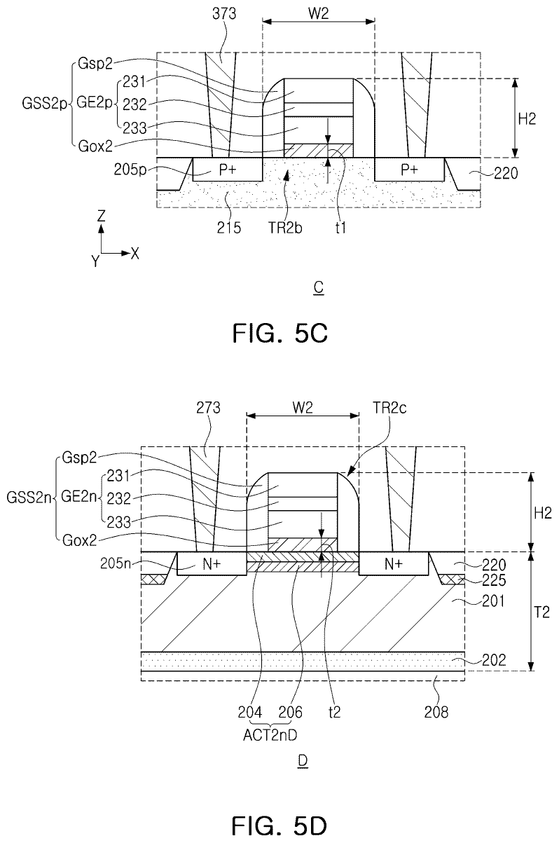

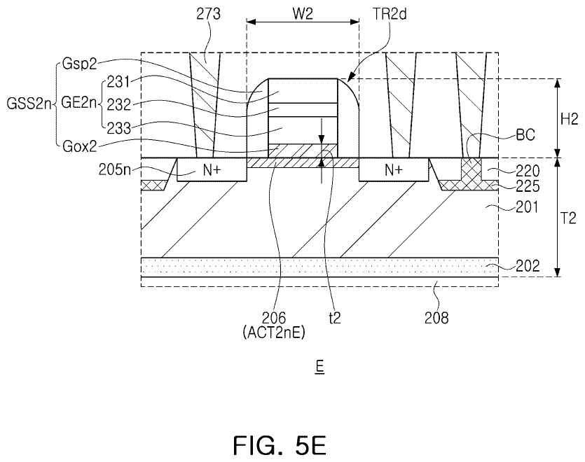

FIG. 4 is a cross-sectional view of the semiconductor device of FIG. 2 according to example embodiments. FIG. 5A is a partially enlarged view of region A of FIG. 4 according to example embodiments. FIG. 5B is a partially enlarged view of region B of FIG. 4 according to example embodiments. FIG. 5C is a partially enlarged view of region C of FIG. 4 according to example embodiments, FIG. 5D is a partially enlarged view of region D of FIG. 4 according to example embodiments, and FIG. 5E is a partially enlarged view of region E of FIG. 4 according to example embodiments. FIGS. 5A, 5B, 5C, 5D, and 5E are views illustrating regions A, B, C, D, and E of FIG. 4 inverted upside down.

Referring to FIG. 4, the semiconductor device 100 may include a cell structure CELL and first and second peripheral circuit structures PERI1 and PERI2. In one example, the semiconductor device 100 may include a cell structure CELL, a second peripheral circuit structure PERI2, and a first peripheral circuit structure PERI1, which are sequentially stacked in a vertical direction (Z-direction).

The semiconductor device 100 may include a cell structure CELL including a base plate 110, a second peripheral circuit structure PERI2 including a second substrate 201 on the cell structure CELL, and a first peripheral circuit structure PERI1 including a first substrate 301 on the second peripheral circuit structure PERI2.

The cell structure CELL may have the cell array region CAR, the cell contact region CTR and the pad region PER, and may include a base plate 110 and a gate structure GS stacked on the base plate 110.

The base plate 110 may be provided to all of cell array region CAR and the pad region PER. The base plate 110 may be in contact with the first channel structure CH, a cell contact 160, and a source contact 170.

First and second horizontal conductive layers 102 and 104 on the base plate 110 may be sequentially stacked and disposed on an upper surface of the base plate 110 in the cell array region CAR. The first horizontal conductive layer 102 may not extend to the cell contact region CTR, and the second horizontal conductive layer 104 may extend to the cell contact region CTR. The first horizontal conductive layer 102 may function as a common source line of the semiconductor device 100 together with the base plate 110. The first horizontal conductive layer 102 may be directly connected (e.g., electrically connected) to the channel layer of the first channel structure CH. The second horizontal conductive layer 104 may be in contact with the base plate 110 in some regions of the cell contact region CTR in which the first horizontal conductive layer 102 and the horizontal insulating layer 105 are not disposed.

The first and second horizontal conductive layers 102 and 104 may include a semiconductor material, for example, polycrystalline silicon. The first horizontal conductive layer 102 may be a layer doped with impurities of the same conductivity type as the base plate 110, and the second horizontal conductive layer 104 may be a doped layer or a layer including impurities diffused from the first horizontal conductive layer 102. However, a material of the second horizontal conductive layer 104 is not limited to a semiconductor material, and may also be replaced with an insulating layer.

A horizontal insulating layer 105 may be disposed on the base plate 110 on the same level as the first horizontal conductive layer 102 in at least a portion of the cell contact region CTR. The horizontal insulating layer 105 may include first and second horizontal insulating layers alternately stacked on the cell contact region CTR of the base plate 110. The horizontal insulating layer 105 may be layers remaining after a portion thereof is replaced with the first horizontal conductive layer 102 during a manufacturing process of the semiconductor device 100. Herein, the term “level”, “vertical level”, “height”, or the like may refer to a relative location with respect to a reference element (e.g., the base plate 110) in the vertical direction (e.g., Z-direction). A level, a vertical level, height, or the like may be a distance from the reference element in the vertical direction. For example, a higher level may mean a farther distance from the reference element in the vertical direction, and a lower level may mean a closer distance to the reference element in the vertical direction.

The horizontal insulating layer 105 may include, for example, silicon oxide, silicon nitride, silicon carbide, and/or silicon oxynitride. The first horizontal insulating layers and the second horizontal insulating layers may include different insulating materials. For example, the first horizontal insulating layers may include (e.g., may be formed of) the same material as interlayer insulating layers 120, and the second horizontal insulating layer may include (e.g., may be formed of) a different material from the interlayer insulating layers 120.

The base plate 110, the first and second horizontal conductive layers 102 and 104 may be provided as a common source line of the semiconductor device 100 (e.g., the common source line GSL of FIG. 1A). The base plate 110 may include polysilicon doped with impurities or a metal, but the present disclosure is not limited thereto.

The base plate 110 may include a front surface and a rear surface opposite to the front surface (in the vertical direction). A gate structure GS may be disposed on the front first of the base plate 110 and the second horizontal conductive layers 102 and 104. A base substrate 101 and an interconnection structure layer 115 disposed on the base substrate 101 may be disposed on the rear surface of the base plate 110.

The base substrate 101 may include a semiconductor material, for example, a group IV semiconductor, a group III-V compound semiconductor, and/or a group II-VI compound semiconductor. The base substrate 101 may be provided as a bulk wafer or an epitaxial layer.

The interconnection structure layer 115 may be a redistribution structure layer for cell interconnection lines 161, 171, 191 and 192 disposed in the cell structure CELL.

The cell structure CELL may include first channel structures CH disposed to extend into (e.g., penetrate through) the gate structure GS in the cell array region CAR, second channel structures SCH, a word line cut structure WLC extending into (e.g., penetrating through) the gate structure GS, an upper electrode 150 disposed on an upper portion of the gate structure GS, an upper horizontal insulating layer 141 disposed between the first channel structures CH and the second channel structures SCH, and a connection pad 143.

The cell structure CELL may include a first cell interlayer insulating layer ILD1 on (e.g., covering or overlapping) gate electrodes 130, an upper electrode 150, second channel structures SCH, a connection pad 143, a second cell interlayer insulating layer ILD2 on (e.g., covering or overlapping) the cell interconnection lines 191 and 192, and a first bonding insulating layer CINS1 disposed in an upper portion of the second cell interlayer insulating layer ILD2.

The cell interconnection lines 191 and 192 may be disposed in (within) the second cell interlayer insulating layer ILD2.

The cell interconnection lines 191 and 192 may be electrically connected to the first and second channel structures CH and SCH, may be electrically connected to the cell contact 160 and may be electrically connected to the source contact 170.

The gate electrodes 130 may be vertically spaced apart from each other and stacked on the front surface of the base plate 110, thus forming the gate structure GS together with the interlayer insulating layers 120. The gate structure GS may include first, second, and third stack structures GS1, GS2 and GS3, which are vertically stacked. However, according to example embodiments, the number of stack structures included in the gate structure GS may be variously changed. For example, in some example embodiments, the gate structure GS may be formed of four or more stack structures or may be formed of a single or double stack structure. The number of gate electrodes 130 included in each of the first, second and third stack structures GS1, GS2 and GS3 may be identical or different.

The upper electrode 150 may form string select transistors (e.g., string select transistor SST of FIG. 1C).

The gate electrodes 130 may include upper gate electrodes 130U included in an erase transistor, memory gate electrode layers 130M included in a plurality of memory cells, and lower gate electrode layers 130L included in an erase transistor and/or a ground select transistor (e.g., a ground select transistor GST of FIG. 1C). The number of memory gate electrode layers 130M included in memory cells may be determined according to the capacity of the semiconductor device 100.

The gate electrodes 130 may be spaced apart from each other and stacked on the cell array region CAR, and may extend from the cell array region CAR to the cell contact region CTR by different lengths, thus forming staircase-shaped step structures (in a cross-sectional view). As illustrated in FIG. 4, the gate electrodes 130 may have a form removed by a predetermined depth from an upper portion of one of the first, second, and third stack structures GS1, GS2 and GS3.

The gate electrodes 130 may include, for example, a metallic material, such as tungsten (W). According to an example embodiment, the gate electrodes 130 may include polycrystalline silicon or a metal silicide material. The gate electrodes 130 may include the same material as a whole. In example embodiments, the gate electrodes 130 may further include a diffusion barrier, for example, the diffusion barrier may include tungsten nitride (WN), tantalum nitride (TaN), titanium nitride (TiN), and/or combinations thereof.

The interlayer insulating layers 120 may be (each) disposed between the (adjacent) gate electrodes 130. The interlayer insulating layers 120 may be spaced apart from each other in the vertical direction (e.g., Z-direction) on a front surface of the base plate 110 and may extend in the first (horizontal direction) direction (e.g., X-direction). The interlayer insulating layers 120 may include, for example, an insulating material such as silicon oxide and/or silicon nitride. In example embodiments, a thickness of each of the interlayer insulating layers 120 may be variously changed.

The first channel structures CH may extend in the vertical direction (e.g., Z-direction) by extending into (e.g., penetrating through) the gate electrodes 130, and may be (electrically) connected to the base plate 110 from a lower portion. Each of the first channel structures CH may form a single memory cell string along with the second channel structures SCH, and may be spaced apart from each other by forming rows and columns on a front surface of the base plate 110 in the cell array region CAR. The first channel structures CH may be disposed on a plane to form a grid pattern or may be disposed in a zigzag shape in one direction. The first channel structures CH may have a columnar shape and may have an inclined side surface that become narrower toward the base plate 110. Some of the first channel structures CH including, for example, a first channel structures CH disposed in an end of the cell array region CAR may be dummy channel structures.

The first channel structures CH may include lower, middle and upper channel structures vertically stacked. The first channel structures CH may have a form in which the lower channel structures, the middle channel structures and the upper channel structures are connected, and may have bent portions due to a difference in width in a connection region thereof. However, according to example embodiments, the number of channel structures stacked in the vertical direction (Z-direction) may be variously changed.

The second channel structure SCH may extend in the vertical direction (Z-direction) by extending into (e.g., penetrating through) the upper electrode 150, and may be (electrically) connected to the first channel structures CH, respectively. The second channel structure SCH may be disposed to be shifted from the first channel structure CH in a horizontal direction, but the present disclosure is not limited thereto. In one example, the second channel structure SCH may be (electrically) connected to the cell interconnection lines 191 and 192.

The cell interconnection lines 191 and 192 may include a conductive material. The first and second channel structures CH and SCH may be electrically connected to the second peripheral circuit structure PERI2 through the cell interconnection lines 191 and 192 and first bonding structures 193 and 195. The first bonding structures 193 and 195 may include a first bonding via 193 disposed on (above) the cell interconnection lines 191 and 192 and (electrically) connected to the cell interconnection lines 191 and 192 and a first bonding pad 195 on and (electrically) connected to the first bonding via 193.

The upper horizontal insulating layer 141 may be disposed between the first channel structure CH and the second channel structure SCH and may extend horizontally. The upper horizontal insulating layer 141 may be disposed between the upper electrode 150 and the upper gate electrode 130U. The upper horizontal insulating layer 141 may be a layer used as an etching stop layer when forming the second channel structure SCH and used when forming the connection pads 143.

The upper horizontal insulating layer 141 may include an insulating material, and may include a different material from the first and second cell interlayer insulating layers ILD1 and ILD2. The upper horizontal insulating layer 141 may be a hydrogen blocking layer and may include a material blocking or reducing diffusion of hydrogen (H). The upper horizontal insulating layer 141 may include, for example, a nitride. The upper horizontal insulating layer 141 may include, for example, SiN, SiON, SiCN, and/or SiOCN.

The connection pads 143 may extend into (e.g., penetrate through) the upper horizontal insulating layer 141 between the first channel structures CH and the second channel structures SCH (in the vertical direction), thus electrically connecting a first channel layer of the first channel structure CH and a second channel layer of the second channel structure SCH. The connection pads 143 may be formed by removing a portion of the upper horizontal insulating layer 141 and may have upper surfaces, coplanar with an upper surface of the upper horizontal insulating layer 141. The connection pads 143 may be disposed in a partially recessed form of the first channel pads of the first channel structure CH. However, the specific arrangement form of the connection pads 143 may be variously changed in example embodiments. The connection pads 143 may include a conductive material, and may include, for example, polycrystalline silicon.

The word line cut structure WLC may have a shape in which a width decreases toward the base plate 110 due to a high aspect ratio. The word line cut structure WLC may include, for example, an insulating material. The word line cut structure WLC may include, for example, silicon oxide, silicon nitride, and/or silicon oxynitride.

The cell contacts 160 may be (electrically) connected to contact regions of the gate electrodes 130 in the cell contact region CTR. The cell contacts 160 may be (electrically) connected to the contact regions of the gate electrodes 130 by penetrating (at least) a portion of the second cell interlayer insulating layer ILD2, the first cell interlayer insulating layer ILD1 and the upper horizontal insulating layer 141. The cell contacts 160 may be (electrically) connected to the cell interconnection lines 191 and 192 disposed in the second cell interlayer insulating layer ILD2. In some example embodiments, the cell contacts 160 may be disposed so as not to penetrate through the gate electrodes 130, in which case, the cell contacts 160 may be (electrically) connected to the contact regions of the gate electrodes 130 exposed upwardly, respectively.

The cell contacts 160 may include, for example, a conductive material, such as tungsten (W), copper (Cu), aluminum (Al), and/or alloys thereof. In some example embodiments, the cell contact 160 may include a barrier layer extending along a side surface and a lower surface (e.g., a bottom surface) of the cell contact 160, or may have an air gap therein.

Contact insulating layers 123 may be disposed to extend around (e.g., at least partially surround) side surfaces of each of the cell contacts 160 below the contact regions. The contact insulating layers 123 may be spaced apart from each other in the vertical direction (e.g., Z-direction) around each of the cell contacts 160. The contact insulating layers 123 may be disposed on (substantially) the same level as the gate electrodes 130, respectively. The contact insulating layers 123 may include, for example, an insulating material, such as silicon oxide, silicon nitride, and/or silicon oxynitride.

An upper contact plug 147 may be electrically connected to the upper electrode 150. The upper contact plug 147 may not penetrate through (e.g., may not extend into) the upper electrode 150. The upper contact plug 147 may be disposed by being partially recessed from an upper surface of the upper electrode 150 or may be disposed to be (electrically) connected to the upper surface of the upper electrode 150. The upper contact plug 147 may include, for example, a conductive material. The upper contact plug 147 may include the same material as the cell contacts 160, but the present disclosure is not limited thereto.

The cell structure CELL may include a source contact 170 (electrically) connected to the base plate 110 in the pad region PER and an input/output contact (electrically) connected to the input/output pad.

The source contact 170 may include (e.g., may be formed of) a metal, a metal compound, and/or a conductive material such as polysilicon, and may be electrically connected to the base plate 110.

The first bonding insulating layer CINS1 and the first bonding pad 195 may be disposed above the cell interconnection lines 191 and 192. In one example, the first bonding insulating layer CINS1 may be on (above) the second cell interlayer insulating layer ILD2. The first bonding pad 195 may be in (e.g., buried in) a lower surface of the first bonding insulating layer CINS1. For example, an upper surface of the first bonding insulating layer CINS1 may be coplanar with an upper surface of the first bonding pad 195, and a lower surface of the first bonding insulating layer CINS1 may not be coplanar with a lower surface of the first bonding pad 195.

The second peripheral circuit structure PERI2 and the first peripheral circuit structure PERI1 may sequentially disposed on an upper portion of the cell structure CELL, thus implementing the peripheral circuit 20 for driving the cell structure CELL.

The first peripheral circuit structure PERI1 may include a first substrate 301, a first peripheral circuit 330 disposed on the first substrate 301, and first peripheral interconnection lines 373 and 385 (electrically) connected to the first peripheral circuit 330. The first peripheral circuit structure PERI1 may include a first peripheral interlayer insulating layer ILD4 on (e.g., covering or overlapping) the first peripheral circuits 330 and the first peripheral interconnection lines 373 and 385.

The first substrate 301 may include a semiconductor material, such as a group IV semiconductor, a group III-V compound semiconductor, and/or a group II-VI compound semiconductor. The first substrate 301 may be provided as a bulk wafer or an epitaxial layer.

The first substrate 301 may have a first thickness T1 in the vertical direction (Z-direction). The first thickness T1 may be, for example, 2 μm to 6 μm, but the present disclosure is not limited thereto.

The first peripheral circuit 330 on the first substrate 301 may include a planar transistor. The first peripheral circuit 330 may have a first operating voltage (low voltage operating voltage).

The first peripheral circuit 330 may include a first page buffer (e.g., the first page buffer 21a of FIG. 1B), a first row decoder (e.g., the first row decoder 22a of FIG. 1B), and a control logic (e.g., the control logic 23 of FIG. 1B). For example, the first peripheral circuit 330 may include a first-first peripheral circuit TR1a overlapping a memory cell array region CAR (in the vertical direction), and may include a first-second peripheral circuit TR1b overlapping a cell contact region CTR (in the vertical direction).

The first-first peripheral circuit TR1a may provide the first page buffer 21a (electrically) connected to the bit line BL of the cell structure CELL through the through-via 240. The first-second peripheral circuit TR1 b may provide the first row decoder 22a (electrically) connected to the word line WL of the cell structure CELL through the through-via 240.

The first peripheral circuit 330 may be disposed on the first substrate 301 so as to face the second peripheral circuit structure PERI2. That is, when the first substrate 301 has a front surface (e.g., a lower surface in FIG. 4) and a rear surface (e.g., an upper surface in FIG. 4), the front surface and the rear surface may be disposed so that the front surface faces the second peripheral circuit structure PERI2 and the rear surface is exposed upwardly. A plurality of first peripheral circuits 330 may be on the front surface of the first substrate 301.

As illustrated in FIG. 4, a P-well region 310 and an N-well region 315 may be disposed on the front surface of the first substrate 301, respectively.

The first-first peripheral circuits TR1a may be disposed in the P-well region 310, and the first-first peripheral circuits TR1a may be NMOS transistors. The first-second peripheral circuits TR1b may be disposed in the N-well region 315, and the first-second peripheral circuits TR1b may be PMOS transistors.

Referring to FIG. 5A, the first-first peripheral circuits TR1a may include a first gate stack GSS1n and a first source/drain region 305n. The P-well region 310 may be a region doped with P-type impurities. The first source/drain region 305n may include an impurity region of a different conductivity type from that of the P-well region 310. In one example, the first source/drain region 305n may include a region doped with N-type impurities.

The first gate stack GSS1n may include a first gate insulating film Gox1, a first gate electrode GE1n, and a first gate spacer Gsp1 on (e.g., covering or overlapping) sidewalls of the first gate insulating film Gox1 and the first gate electrode GE1n. The first source/drain region 305n may include a pair of impurity regions formed in the P-well region 310 of the first substrate 301 on both sides (e.g., opposite sides) of the first gate stack GSS1n.

The first gate insulating film Gox1 may include a high-κ material. The high-κ material may refer to a dielectric material having a higher dielectric constant than a silicon oxide film (e.g., SiO₂). The high-κ material may include (e.g., may be), for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃).

The first gate electrode GE1n may include a first-first gate metal pattern 334, a first gate conductive pattern 333, and first-second gate metal patterns 331 and 332, which are stacked in the vertical direction (Z-direction) on the first gate insulating film Gox1. In one example, the first-first gate metal pattern 334 may include an N-type metal layer. The first gate conductive pattern 333 may include a polysilicon (Poly-Si) layer. The first-second gate metal patterns 331 and 332 may be disposed on the first gate conductive pattern 333 and may include the first-second metal layer 332, different from the first-first metal layer 331. For example, the first-first metal layer 331 may include titanium nitride (TiN) or TSN (Ti—Si—N) and the first-second metal layer 332 may include tungsten (W).

The first gate spacer Gsp1 may be provided as a pair of spacers on the sidewalls of the first gate insulating film Gox1 and the first gate electrode GE1n. The first gate spacer Gsp1 may include (e.g., may be formed of), for example, an oxide film, a nitride film, an oxide-nitride film, and/or combinations thereof.

Referring to FIG. 5B, the first-second peripheral circuit TR1b may include a first gate stack GSS1p and a first source/drain region 305p. The first-second peripheral circuit TR1b may be disposed on the N-well region 315 of the first substrate 301.

The N-well region 315 may be a region doped with N-type impurities.

The first source/drain region 305p may include an impurity region of an opposite conductivity type to that of the N-well region 315. In one example, the first source/drain region 305p may include a region doped with P-type impurities.

The first gate stack GSS1p may include a first gate insulating film Gox1, a first gate electrode GE1p, and a first gate spacer Gsp1 on (e.g., covering or overlapping) sidewalls of the first gate insulating film Gox1 and the first gate electrode GE1p. The first source/drain region 305p may include a pair of impurity regions formed in the N-well region 315 of the first substrate 301 on both sides (e.g., opposite sides) of the first gate stack GSS1p.

The first gate electrode GE1p may include a first-1b gate metal pattern 334b, a first-1a gate metal pattern 334a, a first gate conductive pattern 333, and first-second gate metal patterns 331 and 332, which are stacked in the vertical direction (Z-direction) on the first gate insulating film Gox1. In one example, the first-1b gate metal pattern 334b may include a first conductive metal layer, and the first-1a gate metal pattern 334a may include a second conductive metal layer different from the first conductive metal layer. For example, the first-1b gate metal pattern 334b may include a P-type metal layer, and the first-1a gate metal pattern 334a may include an N-type metal layer. The first gate conductive pattern 333 may include a polysilicon (Poly-Si) layer. The first-second gate metal patterns 331 and 332 may include a first-first metal layer 331 and a first-second metal layer 332 which is disposed on the first-first metal layer 331 and is different from the first-first metal layer 331. For example, the first-first metal layer 331 may include titanium nitride (TiN) or TSN (Ti—Si—N), and the first-second metal layer 332 may include tungsten (W).

The first gate electrode GE1p may further include a metal-semiconductor compound layer 336 (or a metal-semiconductor channel layer) provided in (within) the N-well region 315 between the first source/drain regions 305p (in the first horizontal direction (e.g., X-direction)). The metal-semiconductor compound layer 336 may include a metal element and a semiconductor element. For example, the metal-semiconductor compound layer 336 may include silicon-germanium (SiGe).

The first gate stacks GSS1n and GSS1p of the first peripheral circuits 330 (TR1a and TR1b) may have a first height H1 in the vertical direction (Z-direction), and the first gate insulating film Gox1 of the first gate stacks GSS1n and GSS1p may have a first thickness t1 in the vertical direction (Z-direction). For example, the first thickness t1 may be less than (about) 60 Å.

The first gate insulating film Gox1 may have a first dielectric constant, and may have a high dielectric constant. A channel length of the first peripheral circuits 330 (TR1a and TR1b) may have a first length W1 (in the first horizontal direction (e.g., X-direction)).

In the semiconductor device 100 according to example embodiments of the present disclosure, the components may be divided according to the magnitude of the operating voltage, and a second peripheral circuit 230 having a high level (high voltage) of operating voltage may be disposed relatively adjacently to the cell structure CELL, and the first peripheral circuit 330 having a relatively low level (low voltage) of operating voltage may be disposed to be relatively spaced apart from the cell structure CELL, thereby securing an efficient electrical path and improving the integration level through the efficient arrangement of the first and second peripheral circuits 230 and 330 having operating voltages having different magnitudes.

The first peripheral interconnection lines 373 and 385 may be electrically connected to the first peripheral circuit 330. The first peripheral interconnection lines 373 and 385 may include a first peripheral contact plug 373 and first peripheral contact interconnection lines 385.

The first peripheral contact plug 373 may have a cylindrical shape, and the first peripheral contact interconnection lines 385 may have a line shape. An electrical signal may be applied to the first peripheral circuit 330 by the first peripheral interconnection lines 373 and 385. The first peripheral interconnection lines 373 and 385 may include a conductive material, and each of the components may further include a diffusion barrier. In one example, the number of layers of the first peripheral interconnection lines 373 and 385 may be changed according to various example embodiments.

The first peripheral interlayer insulating layer ILD4 may be disposed to be on (e.g., to cover or overlap) the first peripheral circuit 330 and the first peripheral interconnection lines 373 and 385 disposed on the front surface of the first substrate 301. A first peripheral bonding insulating layer 303 in contact with an upper portion of the second substrate 201 of the second peripheral circuit structure PERI2 may be disposed on the first peripheral interlayer insulating layer ILD4.

The first peripheral interlayer insulating layer ILD4 may include a plurality of insulating layers formed in different processes. The first peripheral interlayer insulating layer ILD4 may include an insulating material.

A passivation layer 302 may be further disposed on a rear surface of the first substrate 301, and pad patterns may be disposed on the passivation layer 302.

The second peripheral circuit structure PERI2 may be disposed between the cell structure CELL and the first peripheral circuit structure PERI1 (in the vertical direction). The second peripheral circuit structure PERI2 may include a second substrate 201 having a front surface and a rear surface, second peripheral circuits 230 disposed on the front surface of the second substrate 201, second peripheral interconnection lines 273 and 285 (electrically) connected to the second peripheral circuits 230, and second bonding structures 293 and 295 electrically connected to the second peripheral interconnection lines 273 and 285.

The second peripheral circuit structure PERI2 may further include a second peripheral interlayer insulating layer ILD3 on (e.g., covering or overlapping) the second peripheral circuits 230, the second peripheral interconnection lines 273 and 285 and the second bonding structures 293 and 295 on a front surface thereof, and a second bonding insulating layer CINS2 disposed on the second peripheral interlayer insulating layer ILD3.

The second substrate 201 may include a semiconductor material, such as a group IV semiconductor, a group III-V compound semiconductor, and/or a group II-VI compound semiconductor. The second substrate 201 may be provided as a bulk wafer or an epitaxial layer. The second substrate 201 may include a semiconductor material of a first conductivity type, and may be, for example, a P-type semiconductor substrate.

The second substrate 201 may have a second thickness T2 that is (substantially) equal to or less than the first thickness T1 of the first substrate 301. The second thickness T2 may be 10 μm or less, for example, 2 μm to 6 μm, but the present disclosure is not limited thereto. The second thickness T2 of the second substrate 201 may include a thickness of a rear doping layer 202 extending from a rear surface in the second substrate to an interior of the second substrate 201, and may thus be defined as a vertical length between the front surface and the rear surface of the second substrate 201.

The second peripheral circuits 230 on the front surface of the second substrate 201 may include planar transistors. The second peripheral circuits 230 may have a second operating voltage (high voltage operating voltage) having a level higher than that of a first operating voltage (low voltage operating voltage).

The second peripheral circuits 230 may include a second page buffer (e.g., the second page buffer 21b of FIG. 1B), a second row decoder (e.g., the second row decoder 22b of FIG. 1B), a common source line driver 25, and a pass circuit (e.g., the pass circuit 26 of FIG. 1B). For example, the second peripheral circuits 230 may include a second-first peripheral circuit TR2a overlapping the cell array region CAR (in the vertical direction), and may include a second-second peripheral circuit TR2b overlapping the cell contact region CTR (in the vertical direction).

Additionally, a second-third peripheral circuit TR2c may be included in the pass circuit region PSR corresponding to the cell array region CAR and the cell contact region CTR and disposed in an edge region, and a second-fourth peripheral circuit TR2d may be further included in the common source line driving region CDRV.

The second-first peripheral circuit TR2a, the second-second peripheral circuit TR2b, the second-third peripheral circuit TR2c, and the second-fourth peripheral circuit TR2d may have the same size.

The second-first peripheral circuit TR2a may provide the second page buffer 21b (electrically) connected to the bit line BL of the cell structure CELL. Some of the second-second peripheral circuits TR2b may provide the second row decoder 22b (electrically) connected to the word line WL of the cell structure CELL. The second-third peripheral circuit TR2c may provide the pass circuit (e.g., the pass circuit 26 of FIG. 1B) together with the second-second peripheral circuit TR2b, and the second-fourth peripheral circuit TR2d may provide the common source line driver 25.

The second peripheral circuits 230 may be disposed on the front surface (e.g., the lower surface in FIG. 4) of the second substrate 201 so as to face the cell structure CELL.

A P-well region 210 and an N-well region 215 may be disposed on the front surface of the second substrate 201, respectively. Among the second peripheral circuits 230, the second-first peripheral circuit TR2a and the second-second peripheral circuit TR2b may be elements formed in the well regions 210 and 215, respectively, and may be transistors of different conductivity types. Specifically, the second-first peripheral circuits TR2a may be disposed in the P-well region 210, and the second-first peripheral circuits TR2a may be NMOS transistors. The second-second peripheral circuits TR2b may be disposed in the N-well region 215, and the second-second peripheral circuits TR2b may be PMOS transistors.

Referring to FIG. 5C, the second-second peripheral circuit TR2b may be disposed on the N-well region 215 of the second substrate 201. The second-second peripheral circuit TR2b may include a second gate stack GSS2p, a second source/drain region 205p.

The N-well region 215 may include N-type impurities. The second source/drain region 205p may include an impurity region of a second conductivity type different from the first conductivity type of the N-well region 215. For example, the second source/drain region 205p may include a region doped with P-type impurities.

The second gate stack GSS2p may include a second gate insulating film Gox2, a second gate electrode GE2p, and a second gate spacer Gsp2 on (e.g., covering or overlapping) sidewalls of the second gate insulating film Gox2 and the second gate electrode GE2p.

The second gate insulating film Gox2 may include, for example, a silicon oxide film (SiO₂), SiON, GeON and/or GeSiO.

The second gate electrode GE2p may include a second gate conductive pattern 233, and second gate metal patterns 231 and 232, which are stacked in the vertical direction (Z-direction) on the second gate insulating film Gox2.

The second gate conductive pattern 233 may include, for example, a polysilicon (Poly-Si) layer. The second gate metal patterns 231 and 232 may include a second-first metal layer 231 and a second-second metal layer 232 which is disposed on the second-first metal layer 231 and is different from the second-first metal layer 231. For example, the second-first metal layer 231 may include titanium nitride (TiN) or TSN (Ti—Si—N), and the second-second metal layer 232 may include tungsten (W).

The second gate spacer Gsp2 may be provided as a pair of spacers on the sidewalls of the second gate insulating film Gox2 and the second gate electrode GE2p. The second gate spacer Gsp2 may include (e.g., may be formed of), for example, an oxide film, a nitride film, an oxide-nitride film, and/or combinations thereof.

The second-second peripheral circuit TR2b may be a PMOS transistor disposed in the N-well region 215, and the second-first peripheral circuit TR2a may be an NMOS transistor disposed in the P-well region 210, and a shape and size thereof may be (substantially) the same as those of the second-second peripheral circuit TR2b.

The second-first peripheral circuit TR2a may be an enhancement transistor (Enhancement TR) that does not include a separate channel layer, but depletion transistors (Depletion TR) that include a separate channel layer may also be disposed in the P-well region 210.

Meanwhile, the second peripheral circuit 230 may further include a second-third peripheral circuit TR2c and a second-fourth peripheral circuit TR2d. The second-third peripheral circuit TR2c and the second-fourth peripheral circuit TR2d may be transistors formed directly within the second substrate 201 without a separate well region.

When the second substrate 201 is a P-type semiconductor substrate, the second-third peripheral circuit TR2c and the second-fourth peripheral circuit TR2d may be NMOS transistors, and the second-third peripheral circuit TR2c may be a depletion transistor (Depletion TR), and the second-fourth peripheral circuit TR2d may be an enhancement transistor (Enhancement TR).

The second-third peripheral circuit TR2c may be driven at a relatively lower voltage than the second-fourth peripheral circuit TR2d. For example, when the second-fourth peripheral circuit TR2 d is driven at an operating voltage of 30 V or less, the second-third peripheral circuit TR2 c may be driven at an operating voltage of 0 V to 29 V.

The second-third peripheral circuit TR2c may have a relatively lower threshold voltage than the second-fourth peripheral circuit TR2d. For example, when a threshold voltage of the second-fourth peripheral circuit TR2 d is 0 V to 0.8 V, a threshold voltage of the second-third peripheral circuit TR2c may satisfy −2.5 V to −2 V, but the present disclosure is not limited thereto. Herein, a negative voltage may be lower than a positive voltage regardless of its absolute value.

The second-third peripheral circuit TR2c may be disposed adjacently to the second-second peripheral circuit TR2b, and the second-second peripheral circuit TR2b and the second-third peripheral circuit TR2c are switch elements, and thus, the second-third peripheral circuit TR2c may be turned on to boost the voltage to a high voltage through a feedback loop, so that the high voltage may be transmitted to the pass transistors of the pass circuit 26, and the second-second peripheral circuit TR2b may block the off current.

The second-third peripheral circuit TR2c may be formed directly on the front surface of the second substrate 201 without a separate well region, as illustrated in FIG. 5D.

When a region on the front surface of the second substrate 201 excluding the N-well region 215 and the P-well region 210 is defined as a non-well region, the non-well region may include a body conductive layer 225 for forming a field with the second-third peripheral circuit TR2c and the second-fourth peripheral circuit TR2d. For example, the non-well region may be free of impurities of N-type and/or P-type. The non-well region may have a concentration of impurities (substantially) less than the concentrations of impurities of the N-well region and/or P-well region.

The body conductive layer 225 may be disposed below an element isolation region 220 defining a region in which the second-third peripheral circuit TR2c and the second-fourth peripheral circuit TR2d are disposed, for example, a shallow trench isolation (STI).

The body conductive layer 225 may have a predetermined thickness, and a thickness of the body conductive layer 225 may be less than a thickness (depth) of a second source/drain region 205n. The body conductive layer 225 may be spaced apart from the rear surface of the second substrate 201. The body conductive layer 225 may be a doping layer including impurities of the same conductivity type as that of the second substrate 201, and when the second substrate 201 is a P-type semiconductor substrate, the body conductive layer 225 may be a doping layer doped with a high concentration of P-type impurities.

The element isolation regions 220 may be formed on the body conductive layer 225 to form a coplanar surface with the front surface of the second substrate 201. The element isolation region 220 may be formed to be buried within a trench, and may include an insulating material, for example, silicon oxide, silicon oxynitride, and/or silicon oxycarbide. Some of the body conductive layer 225 may protrude to the front surface of the second substrate 201 to form a body contact region BC. The body contact region BC may be (electrically) connected to the second peripheral interconnection lines 273, thus receiving a body voltage of the second substrate 201. When viewed from the front surface of the second substrate 201, the body contact region BC may be (at least partially) surrounded by the element isolation region 220. Accordingly, the body contact region BC may be defined as a protrusion portion extending into (e.g., penetrating through) the element isolation region 220 from at least some of the body conductive layer 225 and expending to the front surface of the second substrate 201. The body contact region BC may be a conductive region including the same impurities as the body conductive layer 225. For example, the body contact region BC may be a region including P-type impurities.

The second-third peripheral circuit TR2c of FIG. 5D may include a second gate stack GSS2n and a second source/drain region 205n in a circuit region defined by the element isolation region 220.

The second source/drain region 205n may include an impurity region of a different conductivity type from that of the second substrate 201. For example, when the second substrate 201 is a P-type substrate, the second source/drain region 205n may include a region doped with N-type impurities.

The second gate stack GSS2n may include a second gate insulating film Gox2, a second gate electrode GE2n, and a second gate spacer Gsp2 on (e.g., covering or overlapping) sidewalls of the second gate insulating film Gox2 and the second gate electrode GE2n.

The second gate insulating film Gox2 may include, for example, a silicon oxide film (SiO₂), SiON, GeON, and/or GeSiO.

The second gate electrode GE2n may include a second gate conductive pattern 233 and a second gate metal patterns 231 and 232 stacked on the second gate insulating film Gox2 in the vertical direction (Z-direction).

The second gate conductive pattern 233 may include, for example, a polysilicon (Poly-Si) layer. The second gate metal patterns 231 and 232 may include a second-first metal layer 231 and a second-second metal layer 232 which is disposed on the second-first metal layer 231 and is different from the second-first metal layer 231. For example, the second-first metal layer 231 may include titanium nitride (TiN) or TSN (Ti—Si—N), and the second-second metal layer 232 may include tungsten (W).

The second gate spacer Gsp2 may be provided as a pair of spacers on the sidewalls of the second gate insulating film Gox2 and the second gate electrode GE2n. The second gate spacer Gsp2 may include (e.g., may be formed of) an oxide film, a nitride film, an oxide-nitride film, and/or combinations thereof.

A channel region ACT2nD may be disposed within the second substrate 201 between the second source/drain regions 205n and below the second gate electrode GE2n.

The channel region ACT2nD may include a first channel layer 204 below the front surface of the second substrate 201 and a second channel layer 206 below the first channel layer 204.

The first channel layer 204 is a doped region doped with impurities of a different conductivity type from that of the second substrate 201, and may be a region doped with the same impurities as the source/drain region 205n at a shallow depth.

The first channel layer 204 may be a region doped with N-type impurities. For example, the first channel layer 204 may include P, As and/or Sb.

The second channel layer 206 may be disposed between the source/drain region 205n below the first channel layer 204, and may be a region doped with a different conductivity type from the first channel layer 204, for example, P-type impurities.

The second channel layer 206 may be a region doped with impurities of the same conductivity type as the body conductive layer 225. For example, the second channel layer 206 may be a region including the same impurities as the body conductive layer 225 and doped with the same impurity concentration as the body conductive layer 225.

The second channel layer 206 may include P-type impurities, for example, B, Al, Ga and/or In. In some embodiments, the channel region ACT2nD may be formed at a level (e.g., depth) lower (e.g., shallow or less) than a level (e.g., depth) of the source/drain region 205n, but the present disclosure not limited thereto.

Since the first channel layer 204 may be doped with the same conductivity type as the source/drain region 205n, the second-third peripheral circuit TR2c may operate as a depletion transistor turned on all the times. Accordingly, the second-third peripheral circuit TR2c may operate as a switch transistor turned off only when an off voltage is applied.

Meanwhile, referring to FIG. 5E, the second-fourth peripheral circuit TR2d may be an enhancement transistor without a separate well region, and may be disposed on a front surface of a non-well region of the second substrate 201.

The second-fourth peripheral circuit TR2d may be disposed within a region defined by the element isolation region 220 in an upper portion of the body conductive layer 225.

The body conductive layer 225 may have a predetermined thickness, and a thickness of the body conductive layer 225 may be less than a thickness (depth) of the source/drain region 205n. The body conductive layer 225 may be spaced apart from the rear surface of the second substrate 201. The body conductive layer 225 may be a doping layer including impurities of the same conductivity type as that of the second substrate 201. For example, when the second substrate 201 is a P-type substrate, the body conductive layer 225 may be a doping layer doped with a high concentration of P-type impurities.

The second-fourth peripheral circuit TR2d of FIG. 5E may include a second gate stack GSS2n and a second source/drain region 205n in the circuit region defined by the element isolation region 220.

The second source/drain region 205n may include an impurity region of a different conductivity type from that of the second substrate 201. For example, when the second substrate 201 is a P-type substrate, the second source/drain region 205n may include a region doped with N-type impurities.

The second gate stack GSS2n may include a second gate insulating film Gox2, a second gate electrode GE2n, and a second gate spacer Gsp2 on (e.g., covering or overlapping) sidewalls of the second gate insulating film Gox2 and the second gate electrode GE2n, and may be (substantially) identical to the second gate stack GSS2n of the second-third peripheral circuit TR2c.

A channel layer 206 (ACT2nE) may be disposed within the second substrate 201 between the second source/drain regions 205n and below the second gate electrode GE2n.

The channel layer 206 (ACT2nE) may be formed by being doped at a predetermined depth from a front surface of the second substrate 201, and may be a region disposed between the source/drain regions 205n and doped with P-type impurities having the same conductivity type as the second substrate 201, i.e., the same conductivity type as the body conductive layer 225.

The channel layer 206 (ACT2nE) (e.g., the second channel layer 206) may include P-type impurities, for example, B, Al, Ga and/or In. The channel layer 206 (ACT2nE) may be formed at a depth shallow than a depth of the source/drain region 205n (e.g., the second source/drain region 205n), but is not limited thereto, and may be formed at the same depth as that of the source/drain region 205n of the second-fourth peripheral circuit TR2d. Accordingly, when the channel layer 206 (ACT2nE) may be doped with a different conductivity type from the source/drain region 205n and the second-fourth peripheral circuit TR2d may be turned off all the times, but a voltage equal to or higher than a threshold voltage is applied as a gate voltage, a channel may be formed in the channel layer 206 (ACT2nE) and may operate as an enhancement transistor electrically connected.

The second gate stacks GSS2p and GSS2n of the second-second peripheral circuit TR2b, the second-third peripheral circuit TR2c, and the second-fourth peripheral circuit TR2d in FIGS. 5C, 5D, and 5E may have a second height H2 greater than the first height H1 in the vertical direction (Z-direction). The first gate insulating film Gox1 of the first gate stacks GSS1n and GSS1p may have a first thickness T1 in the vertical direction (Z-direction), and the second gate insulating film Gox2 of the second gate stack GSS2p and GSS2n may have a second thickness T2 greater than the first thickness T1. For example, the first thickness T1 may be less than about 60 Å, and the second thickness T2 may be greater than or equal to (about) 60 Å and less than or equal to (about) 460 Å.

The first gate insulating film Gox1 may have a first dielectric constant, and the second gate insulating film Gox2 may have a second dielectric constant less than the first dielectric constant.

A channel length of the first peripheral circuit 330 may have a first length W1, and a channel length of the second peripheral circuit 230 may have a second length W2 greater than the first length W1. That is, the transistors TR2b, TR2c, and TR2d included in the second peripheral circuits 230 may be greater (than transistors TR1a and TR1b), but the present disclosure is not limited thereto.

Meanwhile, a rear doping layer 202 may be disposed on the rear surface of the second substrate 201, that is, on a rear surface facing the first peripheral circuit structure PERI1. The rear doping layer 202 may be a doping region doped at a predetermined depth from the rear surface of the second substrate 201, and may be formed entirely on the rear surface of the second substrate 201, but the present disclosure is not limited thereto, and unlike FIG. 4, the rear doping layer 202 may be selectively disposed only on a portion (e.g., a rear surface of the non-well region) of the rear surface of the second substrate 201. The rear doping layer 202 may be formed from the rear surface of the second substrate 201 to a predetermined depth, and the predetermined depth may satisfy a depth separated from a lower surface of the body conductive layer 225, and may be greater than a depth of the body conductive layer 225, but the present disclosure is not limited thereto. For example, the rear doping layer 202 may have a concentration gradient such that a concentration of impurities thereof gradually decreases from the rear surface of the second substrate 201 and the concentration of impurities has a value of (near) 0 at (around) the body conductive layer 225, but the present disclosure is not limited thereto.

The rear doping layer 202 may include impurities of the same conductivity type as the body conductive layer 225 and the same conductivity type as the second substrate 201, and may be, for example, a region doped with p-type impurities. The rear doping layer 202 may include P-type impurities, for example, B, Al, Ga and/or In. The impurities of the rear doping layer 202 may be doped at a higher concentration than a concentration of the impurities inside the second substrate 201, and may satisfy, for example, a concentration of 2*E¹⁴/Cm² or less, but the present disclosure is not limited thereto. The rear doping layer 202 may not be biased by having a separate voltage applied thereto and may function as a blocking layer blocking an influence of various charges generated in a region bonded to the first peripheral circuit structure PERI1 in an upper portion and the rear surface of the second substrate 201. Accordingly, the rear doping layer 202 may be clearly distinguished from the contact layer for applying a body voltage to the second substrate 201.

When the semiconductor device 100 is implemented by bonding three structures, as described above, the second peripheral circuit structure PERI2, which is a middle structure, that is the high-voltage peripheral circuit structure may include transistors formed directly in the second substrate 201 in the non-well region in addition to the transistors in the well region. In the case of transistors forming an electric field only with the body conductive layer 225 in the non-well region, when a thickness of the second substrate 201 is sufficiently thick, a depletion region does not reach the rear surface of the substrate (e.g., the second substrate 201) in a turning-on state, and a channel may be formed therein, thus operating as a transistor without leakage current.

The semiconductor device 100 of an example embodiment may be thinned so that the second substrate 201 of a high-voltage second peripheral circuit structure PERI2 has a thickness equal to or less than the first substrate 301 of a low-voltage first peripheral circuit structure PERI1, thereby significantly reducing a height of the semiconductor device 100. In this case, in order to prevent the formation of a parasitic depletion region caused by positive charges generated on the rear surface of the second substrate 201 cut by a thinning process, and leakage currents due to the synthesis of the depletion region of the transistors TR2c and TR2d in the non-well region, the rear doping layer 202 of the first conductivity type may be disposed at a predetermined depth from a thinned rear surface of the second substrate 201. Since the concentration of impurities in the second substrate 201 increases due to the rear doping layer 202, a depth of the depletion region of the transistors (e.g., TR2c and TR2d) in the non-well region may be reduced to be separated from the rear surface of the second substrate 201. Additionally, the formation of the parasitic depletion region due to the positive charges generated on the rear surface of the second substrate 201 may be reduced (e.g., prevented), and an influence of strong currents of the first peripheral interconnection lines 373 and 385 of the first peripheral circuit structure PERI1 close to the rear surface of the second substrate 201 may be blocked.

A substrate insulating layer 208 may be further disposed on the rear surface (e.g., upper surface in FIG. 4) of the second substrate 201. The substrate insulating layer 208 may include the same material as the second peripheral interlayer insulating layer ILD3, but the present disclosure is not limited thereto. A second peripheral bonding insulating layer 203 may be further disposed on the substrate insulating layer 208. The second peripheral bonding insulating layer 203 may include the same material as the first peripheral bonding insulating layer 303 of the first peripheral circuit structure PERI1, and may induce physical bonding of the two structures (e.g., PERI1 and PERI2) through dielectric-to dielectric bonding.

The semiconductor device 100 may further include a through-via 240 extending into (e.g., penetrating) the second substrate 201 and electrically connecting the first peripheral interconnection lines 373 and 385 and the second peripheral interconnection lines 273 and 285.

The through-via 240 may extend into (e.g., penetrate through) (at least) portions of the first and second peripheral interlayer insulating layers ILD3 and ILD4 and the second substrate 201, thus electrically connecting the first peripheral interconnection lines 373 and 385 and the second peripheral interconnection lines 273 and 285. The through-via 240 may have a shape in which a width thereof decreases toward the first peripheral circuit structure PERI1.

The semiconductor device 100 may further include a via insulating film extending around (e.g., surrounding) a side surface of the through-via 240. The via insulating film may include an insulating material, for example, silicon oxide. The through-via 240 may include a through-electrode and a barrier layer, and the barrier layer may be between the through-electrode and the via insulating film. The barrier layer may extend around (e.g., surround) a sidewall of the through-electrode and a lower surface of the through-electrode.

The first peripheral circuit structure PERI1 and the second peripheral circuit structure PERI2 may be a through-silicon via (TSV) structure. The TSV structure may be a structure in which a lower chip including the first peripheral circuit structure PERI1 is manufactured, an intermediate chip including the second peripheral circuit structure PERI2 is manufactured, the intermediate chip is disposed on the lower chip, and a through-via (e.g., the through-via 240 of FIG. 4) extending into (e.g., penetrating through) (at least) portions of the lower chip and the intermediate chip is formed, so that the lower chip is electrically connected to the intermediate chip through the through-via.

On the front surface of the second substrate 201, the second peripheral interconnection lines 273 and 285 may be electrically connected to the second peripheral circuit 230. The second peripheral interconnection lines 273 and 285 may include a second peripheral contact plug 273 and second peripheral contact interconnection lines 285.

The second peripheral contact interconnection line 285 may be disposed between the second bonding via 293 and the second peripheral contact plug 273.

The second peripheral contact plug 273 may have a cylindrical shape, and the second peripheral contact interconnection lines 285 may have a line shape. An electrical signal may be applied to the second peripheral circuit 230 by the second peripheral interconnection lines 273 and 285. The second peripheral contact interconnection lines 285 may be (electrically) connected to the second peripheral contact plug 273, may have a line shape, and may be disposed in a plurality of layers. The second peripheral interconnection lines 273 and 285 may include a conductive material, for example, tungsten (W), copper (Cu), and/or aluminum (Al), and each of the components may further include a diffusion barrier. In one example, the number of layers of the second peripheral interconnection lines 273 and 285 may be changed according to various example embodiments.

The second peripheral interlayer insulating layer ILD3 on (e.g., covering or overlapping) the second peripheral circuit 230 and the second peripheral interconnection lines 273 and 285 disposed on the second substrate 201 may be disposed. The second peripheral interlayer insulating layer ILD3 may include a plurality of insulating layers formed in different processes. The second peripheral interlayer insulating layer ILD3 may include an insulating material.

The second bonding insulating layer CINS2 may be disposed on the second peripheral interlayer insulating layer ILD3. The second bonding pad 295 may be disposed on the second peripheral interconnection lines 273 and 285. The second bonding pad 295 may be buried in an upper surface of the second bonding insulating layer CINS2. For example, according to FIG. 4, a lower surface of the second bonding insulating layer CINS2 may be coplanar with an upper surface of the second bonding pad 295, and an upper surface of the second bonding insulating layer CINS2 may not be coplanar with an upper surface of the second bonding pad 295.

The second bonding via 293 may be disposed above (in FIG. 4) the second bonding pad 295 and (electrically) connected to the second bonding pad 295.

The cell structure CELL and the second peripheral circuit structure PERI2 may be bonded by the first and second bonding pads 195 and 295 and the first and second bonding insulating layers CINS1 and CINS2. The bonding of the first and second bonding pads 195 and 295 may be, for example, copper (Cu)-to-copper (Cu) bonding, and the bonding of the first and second bonding insulating layers CINS1 and CINS2 may be, for example, dielectric-to-dielectric bonding, such as SiCN-to-SiCN bonding. The cell structure CELL and the second peripheral circuit structure PERI2 may be bonded by hybrid bonding including, for example, copper (Cu)-to-copper (Cu) bonding and dielectric-to-dielectric bonding.

The cell structure CELL and the second peripheral circuit structure PERI2 may be (electrically) connected through the first bonding structures 193 and 195 and the second bonding structures 293 and 295.

In the semiconductor device 100 according to example embodiments of the present disclosure, the components may be divided according to the magnitude of the operating voltage, and the second peripheral circuit 230 having a high operating voltage may be disposed relatively adjacently to the cell structure CELL, and the first peripheral circuit 330 having a relatively low operating voltage may be relatively spaced apart from the cell structure CELL, and the substrate 201 of the second peripheral circuit structure PERI2 may be simultaneously thinned, thereby improving the integration level.

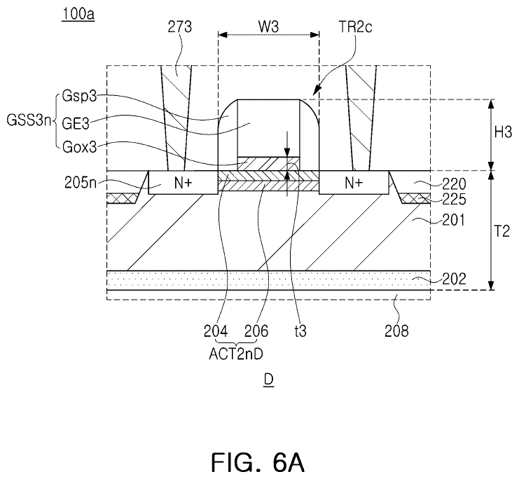

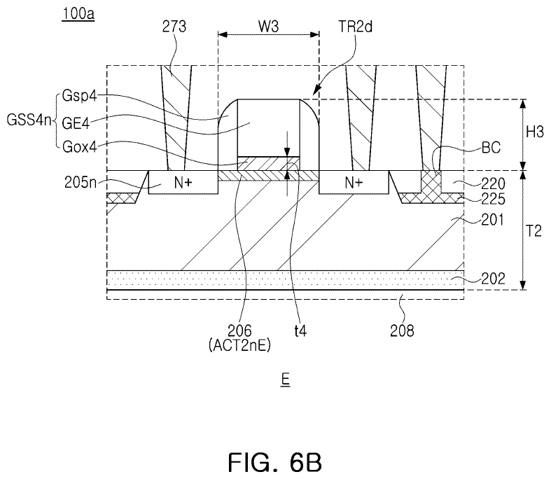

FIG. 6A and FIG. 6B are partially enlarged views according to some example embodiments of the semiconductor device of FIG. 2.

The remaining components of a semiconductor device 100a of FIGS. 6A and 6B excluding the second-third peripheral circuit TR2c and the second-fourth peripheral circuit TR2d of the second peripheral circuit structure PERI2 may be identical to or similar to the components of the semiconductor device 100 of FIG. 4.

In the second-third peripheral circuit TR2c and the second-fourth peripheral circuit TR2d of the second peripheral circuit structure PERI2, a size of a third gate stack GSS3n may be less than a size of the second gate stack GSS2n of FIG. 4. However, the sizes of the second-third peripheral circuit TR2c and the second-fourth peripheral circuit TR2d may be greater than the first peripheral circuits 330 of the first peripheral circuit structure PERI1.

The second-third peripheral circuit TR2c and the second-fourth peripheral circuit TR2d may have the same size. That is, a height of the third gate stack GSS3n of the second-third peripheral circuit TR2c may be greater than the first gate stack GSS1n of the first peripheral circuit 330.

Referring to FIG. 6A, the second-third peripheral circuit TR2c may be disposed on the second substrate 201. The second-third peripheral circuit TR2c may include the third gate stack GSS3n and the second source/drain region 205n.

The second-third peripheral circuit TR2c formed without including separate conductive impurities within the second substrate 201 may include an impurity region of a second conductivity type different from the first conductivity type of the second substrate 201. For example, when the second substrate 201 is a P-type substrate, the second source/drain region 205n may include a region doped with N-type impurities.

The third gate stack GSS3n may include a third gate insulating film Gox3, a third gate electrode GE3, and a third gate spacer Gsp3 on (e.g., covering or overlapping) sidewalls of the third gate insulating film Gox3 and the third gate electrode GE3.

Unlike the second gate stack GSS2n of FIG. 5D, the third gate stack GSS3n (e.g., the third gate electrode GE3) may be implemented as a single layer of a gate metal layer, and may further include a mask layer on the gate metal layer according to an example embodiment.

Referring to FIG. 6B, the second-fourth peripheral circuit TR2d may be disposed on the second substrate 201. The second-fourth peripheral circuit TR2d may include a fourth gate stack GSS4n and a second source/drain region 205n.

The fourth gate stack GSS4n may include a fourth gate insulating film Gox4, a fourth gate electrode GE4, and a fourth gate spacer Gsp4 on (e.g., covering or overlapping) sidewalls of the fourth gate insulating film Gox4 and the fourth gate electrode GE4.

The fourth gate stack GSS4n may include (substantially) the same components as those of the third gate stack GSS3n of FIG. 6A.

In this manner, the second-third peripheral circuit and the second-fourth peripheral circuits TR2c and TR2d of the second substrate 201, i.e., transistors formed directly on the second substrate 201, may have a smaller size than transistors formed within the well region. That is, the second-third peripheral circuit and the second-fourth peripheral circuits TR2c and TR2d may have a third height H3 of the third and fourth gate stacks GSS3n and GSS4n in the vertical direction (Z-direction). The third height H3 may be greater than the first height H1 of the first gate stacks GSS1p and GSS1n and may be less than the second height H2 of the second gate stack GSS2p (and GSS2n).

A third thickness t3 of the third gate insulating film Gox3 and a fourth thickness t4 of the fourth gate insulating film Gox4 in the vertical direction (Z-direction) may be less than the thickness t2 of the second gate insulating film Gox2. The third gate insulating film Gox3 and the fourth gate insulating film Gox4 may have a second dielectric constant less than the first dielectric constant (of the first gate insulating film Gox1).

A channel length of the second-third peripheral circuit and the second-fourth peripheral circuits TR2c and TR2d may have a third length W3. The third length W3 may be greater than the first length W1 of the first peripheral circuit 330, and may be less than the second length W2 of the second peripheral circuit 230 (e.g., the second-second peripheral circuit TR2b).

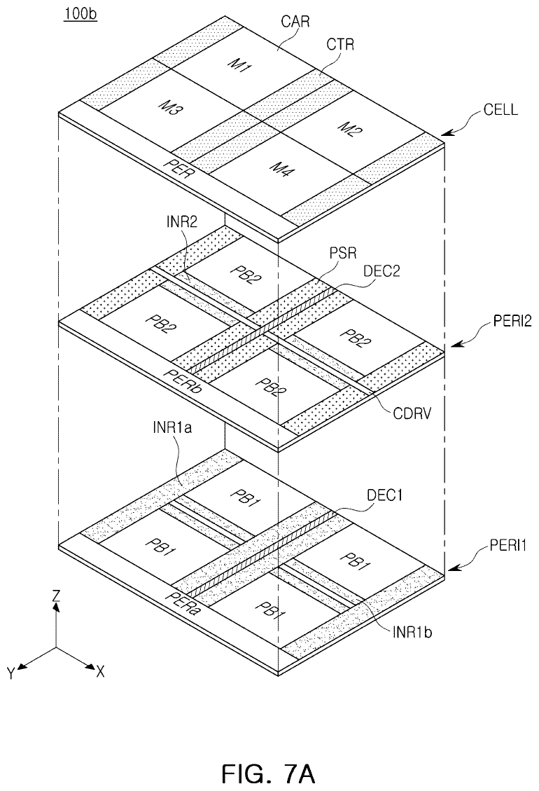

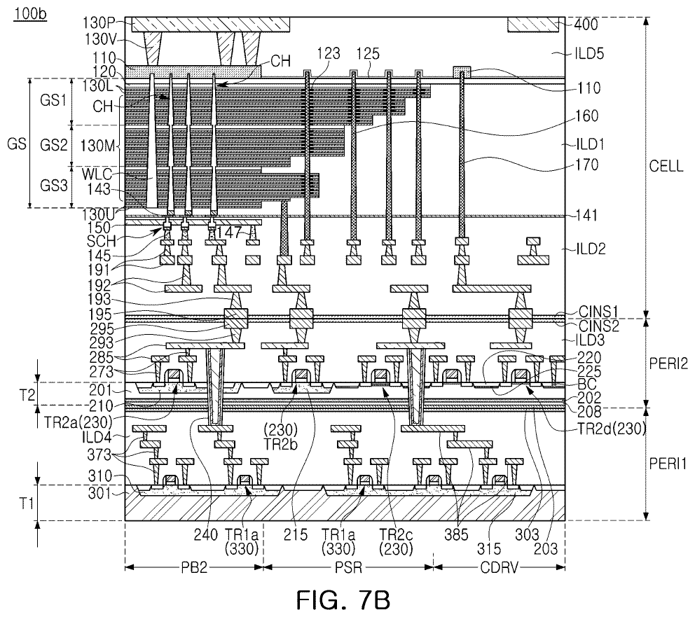

FIG. 7A is a schematic perspective view of a semiconductor device according to some example embodiments, and FIG. 7B is a cross-sectional view of the semiconductor device of FIG. 7A according to an example embodiment.

A semiconductor device 100b may have a cell structure CELL disposed on the second peripheral circuit structure PERI2. In one example, the semiconductor device 100b may include a first peripheral circuit structure PERI1, a second peripheral circuit structure PERI2, and a cell structure CELL sequentially stacked in a vertical direction (Z-direction).

The semiconductor device 100b may include a cell structure CELL including a common source plate 110, a first peripheral circuit structure PERI1 including a first substrate 301, and a second peripheral circuit structure PERI2 including a second substrate 201.

The common source plate 110 may be provided in a cell array region CAR. The common source plate 110 may be in contact with the first channel structure CH. An insulating film 125 may be disposed on a portion of the cell contact 160 horizontally adjacent to the common source plate 110.

The common source plate 110 may include a front surface and a rear surface opposite to the front surface (in the vertical direction). A gate structure GS may be disposed on the front surface (a lower surface in FIG. 7B) of the common source plate 110. An upper interlayer insulating layer ILD5 and interconnection structure layers 130V and 130P disposed within the upper interlayer insulating layer ILD5 may be disposed on a rear surface (e.g., an upper surface in FIG. 7B) of the common source plate 110.

The interconnection structure layers 130V and 130P may be interconnection layers applying a common source voltage. An input/output pad 400 may be disposed on an upper surface of the upper interlayer insulating layer ILD5 on the cell structure CELL.

The memory cell structure CELL may include a first cell interlayer insulating layer ILD1 on (e.g., covering or overlapping) the gate electrodes 130, a second cell interlayer insulating layer ILD2 on (e.g., covering or overlapping) the upper electrodes 150, the second channel structures SCH, the connection pad 143 and the cell interconnection lines 191 and 192, and a first bonding insulating layer CINS1 disposed in a lower portion of the second cell interlayer insulating layer ILD2.

The first bonding insulating layer CINS1 and the first bonding pad 195 may be disposed on the cell interconnection lines 191 and 192. In one example, the first bonding insulating layer CINS1 may be disposed in a lower portion of the second cell interlayer insulating layer ILD2. The first bonding pad 195 may be buried in an upper surface of the first bonding insulating layer CINS1. For example, according to FIG. 7B, a lower surface of the first bonding insulating layer CINS1 may be coplanar with a lower surface of the first bonding pad 195, and an upper surface of the first bonding insulating layer CINS1 may not be coplanar with an upper surface of the first bonding pad 195.

The second peripheral circuit structure PERI2 may be disposed below the memory cell structure CELL.

The second peripheral circuit structure PERI2 may include a second substrate 201, a second peripheral circuit 230 disposed on an upper surface of the second substrate 201, second peripheral interconnection lines 273 and 285 (electrically) connected to the second peripheral circuit 230, and second bonding structures 293 and 295 electrically connected to the second peripheral interconnection lines 273 and 285. The second peripheral circuit structure PERI2 may further include a second peripheral bonding insulating layer 203 disposed on the rear surface (e.g., an upper surface in FIG. 7B) of the second substrate 201.

The second peripheral circuit structure PERI2 may include a second peripheral interlayer insulating layer ILD3 disposed on the upper surface of the second substrate 201 and on (e.g., covering or overlapping) the second peripheral circuit 230, the second peripheral interconnection lines 273 and 285 and the second bonding structures 293 and 295.

The second substrate 201 may include a rear surface facing the first peripheral circuit structure PERI1 and a front surface facing the cell structure CELL.

The second peripheral circuit structure PERI2 may further include a through-via 240 extending into (e.g., penetrating) the second substrate 201 and electrically connecting the second peripheral interconnection lines 273 and 285.

The through-via 240 may electrically connect the first peripheral circuit structure PERI1 disposed on the rear surface of the second substrate 201 and the second peripheral interconnection lines 273 and 285 disposed on the front surface of the second substrate 201 by extending into (e.g., penetrating through) a portion of the second peripheral interlayer insulating layer ILD3 and the second substrate 201.

The first peripheral circuit structure PERI1 may be disposed below the second peripheral circuit structure PERI2.

The first peripheral circuit structure PERI1 may include a first substrate 301, a first peripheral circuit 330 disposed on the front surface (e.g., an upper surface in FIG. 7B) of the first substrate 301, and first peripheral interconnection lines 373 and 385 (electrically) connected to the first peripheral circuit 330.

The semiconductor device 100b may have a structure in which the cell structure CELL is disposed in an uppermost end and the common source plate 110 is disposed in an upper portion, and may be disposed so that a width of the channel structures CH increases toward a lower portion. In a region in which the common source plate 110 and the channel structures CH come into contact with each other, the channel dielectric layer may be removed so that the channel layer and the common source plate 110 may be in direct contact with each other.

In the semiconductor device 100b, the second substrate 201 may also have a second thickness T2, and the second thickness T2 may be 2 μm to 6 μm, but the present disclosure is not limited thereto. The second substrate 201 may be made thinner to induce miniaturization of the semiconductor device 100b, and may minimize an influence of positive charges due to thinning by forming a rear doping layer 202 on the rear surface of the second substrate 201.

The first substrate 301 may have a thickness (a first thickness T1) greater than that of the second substrate 201, and may be, for example, 6 μm to 10 μm, and may function as a supporting substrate of the semiconductor device 100b.

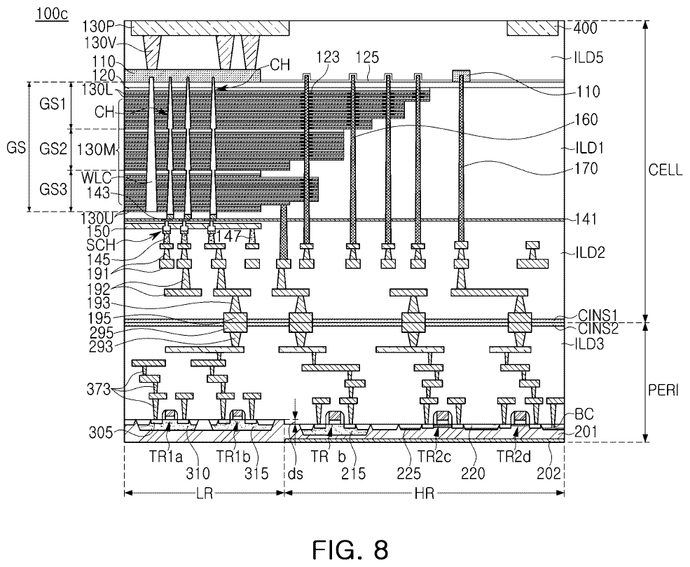

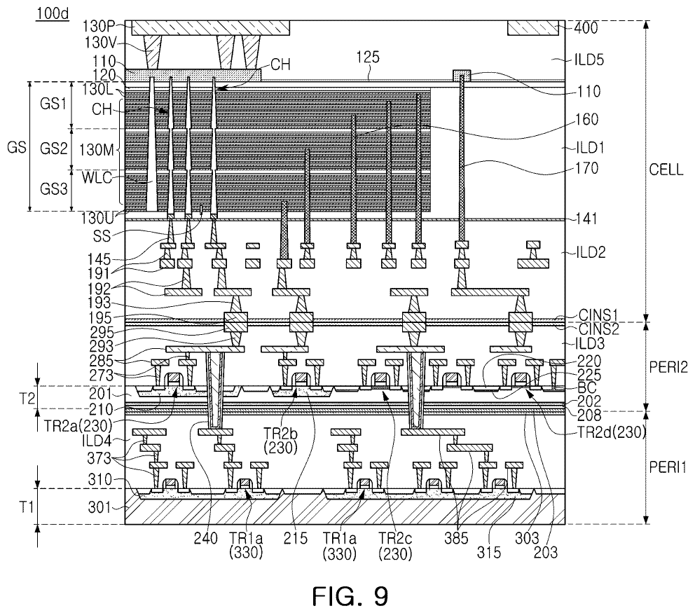

FIGS. 8 and 9 are cross-sectional views illustrating semiconductor devices according to some example embodiments.

A semiconductor device 100c of FIG. 8 is similar or (substantially) identical to the semiconductor device 100b of FIG. 7B except that the first peripheral circuit structure PERI1 and the second peripheral circuit structure PERI2 are implemented as a single structure PERI.

The semiconductor device 100c of FIG. 8 may provide a two-stage structure of the peripheral circuit structure PERI and the cell structure CELL.

The peripheral circuit structure PERI may include a low-voltage peripheral circuit region LR and a high-voltage peripheral circuit region HR within the peripheral circuit substrate 201 including a front surface (e.g., an upper surface in FIG. 8) and a rear surface (e.g., a lower surface in FIG. 8), respectively.

The low-voltage peripheral circuit region LR may include an P-well region 310 and an N-well region 315 from the front surface of the peripheral circuit substrate 201, and may include a first-first peripheral circuit TR1a and first-second peripheral circuits TR1b disposed in the first peripheral circuit structure PERI1 of FIG. 7B in each well regions 310 and 315, respectively. The configuration of the first-first peripheral circuit TR1a and the first-second peripheral circuits TR1b may be similar or (substantially) identical to that of FIG. 5A and FIG. 5B.

A front surface of the high-voltage peripheral circuit region HR may have a step portion ds from a front surface of the low-voltage peripheral circuit region LR and may include an N-well region 215 and a non-well region without a well region.

The high-voltage peripheral circuit region HR may be defined as a region including the second-first, second-second, second-third, and second-fourth peripheral circuits TR2a, TR2b, TR2c, and TR2d of the second peripheral circuit structure PERI2 of FIG. 7B.

That is, the second-second peripheral circuits TR2b, which are P-type transistors, may be disposed in the N-well region 215 of the high-voltage peripheral circuit region HR, and the second-third peripheral circuits TR2c, which are N-type depletion transistors, and the second-fourth peripheral circuits TR2d, which are N-type enhancement transistors, may be disposed in the non-well region.

The configurations of each of the second-first, second-second, second-third, and second-fourth peripheral circuits TR2a, TR2b, TR2c, and TR2d may be identical to that of FIG. 5C to FIG. 5E, and the peripheral circuit substrate 201 may be identical to that of the second substrate 201. That is, the peripheral circuit substrate 201 (e.g., the second substrate 201) may have a third thickness t3, and the third thickness t3 may be 2 μm to 6 μm, but the present disclosure is not limited thereto.

While implementing the low-voltage peripheral circuits TR1a and TR1b and the high-voltage peripheral circuits TR2a, TR2b, TR2c, and TR2d together in a single substrate, the rear doping layer 202 may be included on the rear surface of the peripheral circuit substrate 201 in order to prevent a depletion region synthesis of the high-voltage peripheral circuits TR2a, TR2b, TR2c, and TR2d within the non-well region (e.g., the second-third peripheral circuit TR2c and the second-fourth peripheral circuit TR2d). The rear doping layer 202 may be formed by doping with impurities of the same conductivity type as that of the peripheral circuit substrate 201, for example, P-type impurities. In this case, the rear doping layer 202 may be disposed only within the high-voltage peripheral circuit regions HR, but the present disclosure is not limited thereto.

A semiconductor device 100d of FIG. 9 may be similar or (substantially) identical to the semiconductor device 100b of FIG. 7B except for the shape of the gate electrodes 130 and the interlayer insulating layer 120, and the cell contacts 160 and the upper channel structures SCH (e.g., the second channel structure SCH in FIG. 7B),

The semiconductor device 100d of FIG. 9 may have a structure in which the gate electrodes 130 and the interlayer insulating layer 120 extend continuously to the cell region CAR and the cell contact region CTR without a step portion. Accordingly, all the gate electrodes 130 of the stack structures GS may be disposed to have (substantially) the same area, and do not expose the pad region.

The cell contacts 160 may extend by extending into (e.g., penetrating) through the gate electrodes 130 below an assigned gate electrode 130 so as to contact a lower surface of the assigned gate electrode 130. Side insulating layers on (e.g., covering or overlapping) side surfaces of the cell contacts 160 and opening an upper surface thereof may be further disposed. Accordingly, the cell contacts 160 may extend by different lengths to directly contact the lower surfaces of the assigned gate electrodes 130, thereby enabling contact with the gate electrodes 130 without step portions of the gate electrodes 130.

In the semiconductor device 100d of FIG. 9, a separate upper channel structure SCH is not disposed, and the semiconductor device 100d may include upper insulating regions SS extending along the word line cut structure WLC and cutting an upper gate electrodes 130u. The upper insulating regions SS may extend in the same direction as an extension direction of the word line cut structure WLC between adjacent word line cut structures WLC to divide only the upper gate electrodes 130U into a plurality of sections. Accordingly, the upper gate electrodes 130U (which is on the lower portion of the stack structure GS in FIG. 9), for example, the string selection gate electrodes, may be divided into the plurality of sections, which are (electrically) connected by the respective cell contacts (e.g., string selection contacts) 160, so that a separate upper conductive layer may not be disposed.

The upper insulating regions SS may be disposed to extend into (e.g., penetrate through) at least a portion of the lower portion of the channel structures CH, but the present disclosure is not limited thereto.

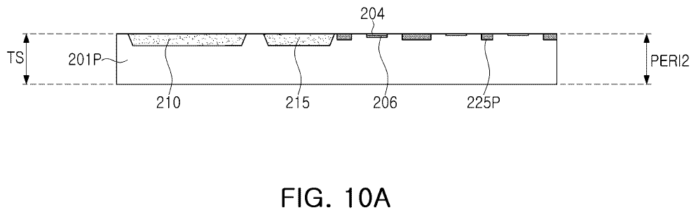

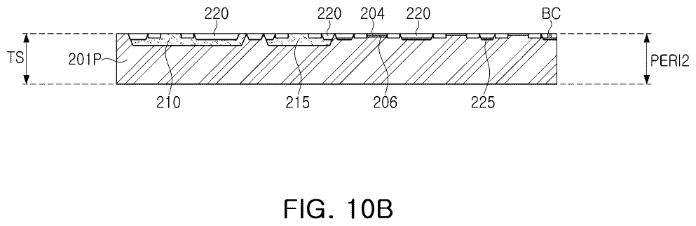

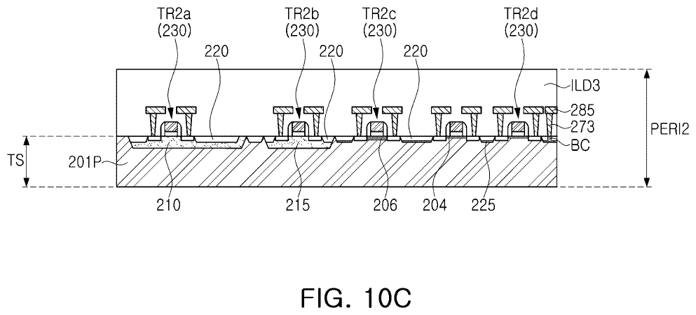

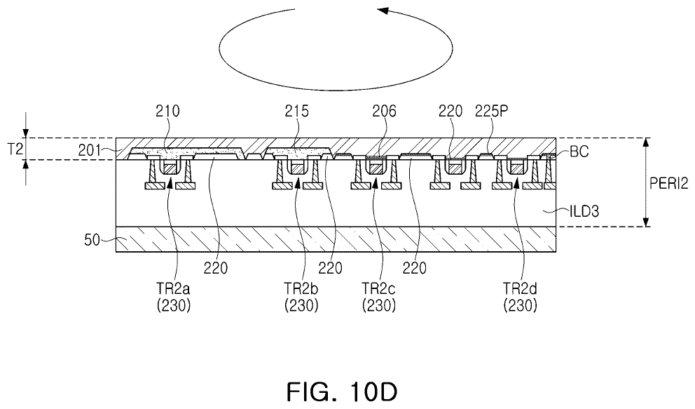

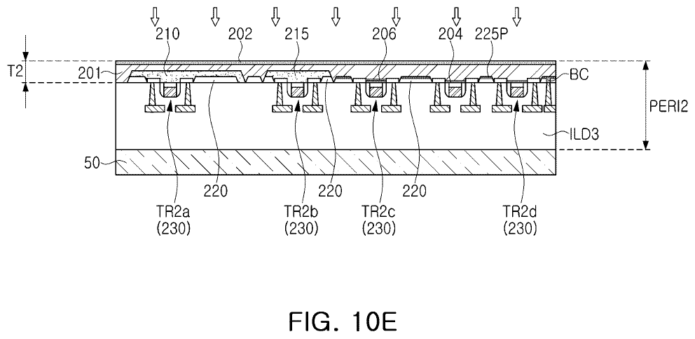

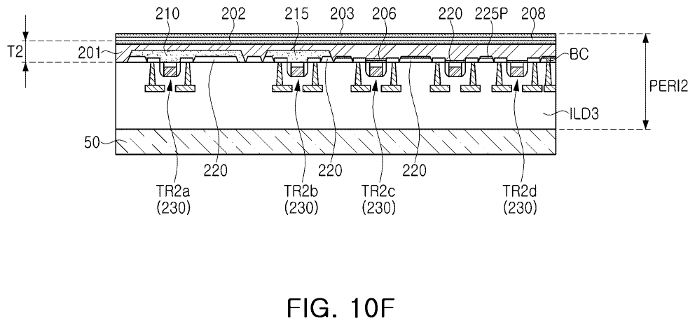

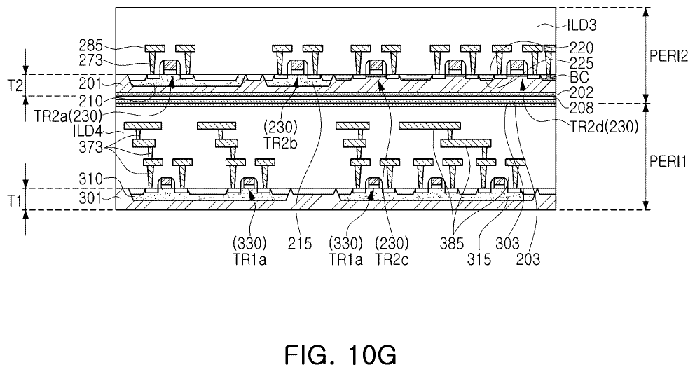

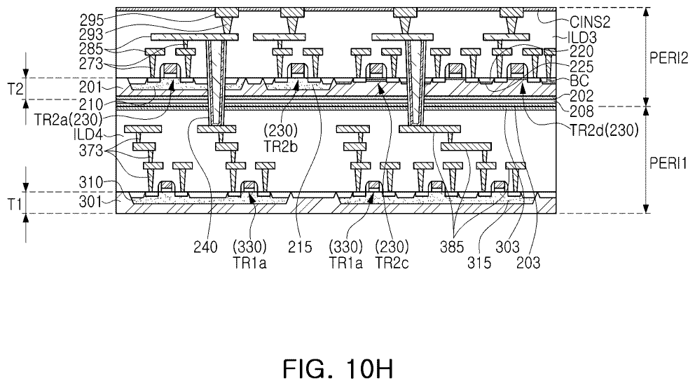

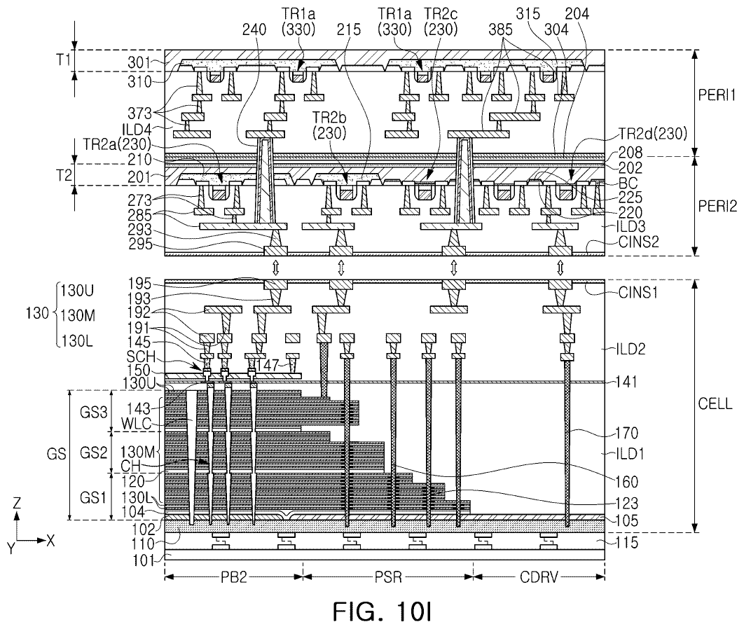

FIGS. 10A, 10B, 10C, 10D, 10E, 10F, 10G, 10H, and 10I are views illustrating example embodiments of methods for manufacturing a semiconductor device of FIG. 4.

Referring to FIG. 10A, a second preliminary substrate 201P for forming a second peripheral circuit structure PERI2 may be prepared.

The second preliminary substrate 201P may have a substrate thickness TS, and the substrate thickness TS may be 20 μm to 30 μm. The N-well region 215 and the P-well region 210 for forming the second peripheral circuits 230 on a front surface (an upper surface in FIG. 10A) of the second preliminary substrate 201P may be formed through doping, respectively.

In this case, within the non-well region, the second channel layer 206 may be formed in the channel regions ACT2nD and ACT2nE of the second-third peripheral circuit TR2c and the second-fourth peripheral circuit TR2d which represent the depletion transistor and the enhancement transistor, respectively. The second channel layer 206 may be formed by doping impurities of the first conductivity type in the same manner as the second preliminary substrate 201P, and the doping thereof may be performed to be lower than a depth of the source/drain region 205n. In this case, a depth of the second channel layer 206 which is a depletion type may be greater.

Meanwhile, impurities of a second conductivity type may be doped onto the second channel layer 206 of the second-third peripheral circuit TR2c, which is a depletion transistor, thus forming a first channel layer 204.

In the first channel layer 204, doping may be performed by a predetermined depth from the front surface of the second preliminary substrate 201P, and the first channel layer 204 may be formed at a depth less (shallower) than that of the second channel layer 206, so that the second channel layer 206 may remain below the first channel layer 204.

Meanwhile, doping may be performed to form a preliminary body conductive layer 225P in a region in which the element isolation region 220 is disposed.

The preliminary body conductive layer 225P may be formed by doping impurities of the first conductivity type, i.e., impurities of the same conductivity type as that of the second preliminary substrate 201P, from the front surface of the second preliminary substrate 201P to a depth of the body conductive layer 225 of FIG. 4. When the second preliminary substrate 201P is a P-type semiconductor substrate, P-type impurities such as boron, aluminum, and/or germanium may be doped.

Referring to FIG. 10B, when doping from the front surface of the second preliminary substrate 201P is completed, an element isolation region 220 may be formed to define active regions.

The element isolation region 220 may be formed by etching a region excluding the active regions by a predetermined depth and then filling the etched region with an insulating material, and a trench device isolation (STI) method may be applied thereto. In this case the element isolation region 220 in the non-well region may be formed by removing the preliminary body conductive layer 225P. Accordingly, only a portion of a lower portion (e.g., a lower surface) of the preliminary body conductive layer 225P may remain so that the preliminary body conductive layer 225P may be spaced apart from the front surface of the second preliminary substrate 201P, thereby forming the body conductive layer 225. An element isolation region 220 may be formed on the body conductive layer 225.

In this case, a body contact region BC for applying a body voltage by protruding from the body conductive layer 225 to the front surface of the second preliminary substrate 201P may be formed, and a trench for the element isolation region 220 may be formed by performing an etching process so that the body contact region BC remains and then filling an etched portion with an insulating material.

Referring to FIG. 10C, a second peripheral circuit structure PERI2 including second-first, second-second, second-third, and second-fourth peripheral circuits TR2a, TR2b, TR2c, and TR2d and a second peripheral interlayer insulating layer ILD3 on (e.g., covering or overlapping) the second-first, second-second, second-third, and second-fourth peripheral circuits TR2a, TR2b, TR2c, and TR2d may be formed (in each region).

The second-first, second-second, second-third, and second-fourth peripheral circuits TR2a, TR2b, TR2c, and TR2d may be peripheral circuit elements having a high operating voltage. For example, the second-second peripheral circuit TR2b may be a switch circuit of the pass circuit, and the second-third peripheral circuit TR2c adjacent to the peripheral circuit TR2b may be a depletion transistor and may be a switch circuit of the pass circuit. Additionally, the second-fourth peripheral circuit TR2d may include a common source line driver (e.g., the common source line driver 25 of FIG. 1B).

The gate stacks of the second peripheral circuit 230 may have (substantially) the same structure, but the present disclosure is not limited thereto.

The second peripheral interlayer insulating layer ILD3 may be formed on (e.g., covering or overlapping) the second peripheral circuit 230 on the front surface of the second substrate 201 of the second peripheral circuit structure PERI2, and portions of the second peripheral interconnection lines 273 and 285 may be formed in (within) the second peripheral interlayer insulating layer ILD3.

Referring to FIG. 10D, the second peripheral circuit structure PERI2 may be inverted and disposed so that the upper surface of the second peripheral interlayer insulating layer ILD3 in FIG. 10C comes into contact with the carrier substrate 50.

Accordingly, the rear surface of the second preliminary substrate 201P may be exposed upwardly. Thinning may be performed so that the substrate thickness TS of the second preliminary substrate 201P is reduced to the second thickness T2.

The second preliminary substrate 201P may be (partially) removed and thinned through a lapping process, a grinding process, a polishing process, or an etching process.

The rear surface of the second substrate 201 may be defined by the thinning (the rear surface of the second preliminary substrate 201P), and the second substrate 201 may have the second thickness T2, for example, a thickness of 2 μm to 6 μm. In this thinning process, positive charges may be applied to the rear surface of the second substrate 201 by slurry or an etchant.

Referring to FIG. 10E, impurities of the first conductivity type identical to the conductivity type of the second substrate 201 may be injected into the rear surface of the second substrate 201. The first conductivity type, e.g., P-type impurities such as B, Al, Ga and/or In may be ion-injected, and a concentration of the impurities may satisfy a concentration of 2*E¹⁴/Cm² or less, but the present disclosure is not limited thereto.

The impurities of the first conductivity type may be injected and then annealed, thus activating the impurities of the first conductivity type. Accordingly, a rear doping layer 202 may be formed from (on) the rear surface of the second substrate 201 by a predetermined depth. The predetermined depth may satisfy a depth separated from the lower surface of the body conductive layer 225. For example, in the rear doping layer 202, a concentration of impurities thereof may gradually decrease from the rear surface of the second substrate 201 and may have a value of (near) 0 at the body conductive layer 225, but the present disclosure is not limited thereto.

The rear doping layer 202 may not be biased by having a separate voltage applied thereto and may function as a blocking layer blocking an influence of various charges generated in a region bonded to the first peripheral circuit structure PERI1 on the upper side.

In the non-well region within the second substrate 201, in the case of transistors implemented only with the body conductive layer 225, when the thickness of the second substrate 201 is reduced due to thinning, unnecessary parasitic depletion regions generated by positive charges applied to the rear surface of the second substrate 201 may be reduced (e.g., prevented) from having an influence by the rear doping layer 202.

As illustrated in FIG. 10F, after the rear doping layer 202 is formed, a substrate insulating layer 208 and a second peripheral bonding insulating layer 203 may be sequentially formed in an upper portion of the rear doping layer 202.

The substrate insulating layer 208 may include an insulating material such as silicon oxide, silicon nitride, and/or silicon oxycarbide, and the second peripheral bonding insulating layer 203 may include the same material as the first peripheral bonding insulating layer 303 of the first peripheral circuit structure PERI1, and may include, for example, silicon nitride. When the second peripheral bonding insulating layer 203 is formed, the second peripheral circuit structure PERI2 may be completed.

As illustrated in FIG. 10G, the second peripheral circuit structure PERI2 and the first peripheral circuit structure PERI1 may be bonded to each other.

The first peripheral circuit structure PERI1 may be formed separately. The first peripheral circuit structure PERI1 may be formed to include the first peripheral circuit 330 formed on the first substrate 301 and the first peripheral interlayer insulating layer ILD4 on (e.g., covering or overlapping) the first peripheral circuit 330.

Specifically, an operation of forming a first peripheral circuit 330 and first peripheral interconnection lines 373 and 385 electrically connected to the first peripheral circuit 330 on the first substrate 301 and an operation of forming a first peripheral interlayer insulating layer ILD4 on (e.g., covering or overlapping) the first peripheral circuit 330 and the first peripheral interconnection lines 373 and 385 may be preceded.

The first peripheral circuit 330 may be a peripheral circuit element having a low-voltage operating voltage. For example, the first-first peripheral circuit TR1a may include a first page buffer (e.g., the first page buffer 21a of FIG. 1B). The first-second peripheral circuit TR1b adjacent to the first-first peripheral circuit TR1a may include a first row decoder (e.g., the first row decoder 22a of FIG. 1B).

A first peripheral bonding insulating layer 303 may be formed on an upper surface of the first peripheral interlayer insulating layer ILD4.

While bonding the first peripheral bonding insulating layer 303 of the first peripheral interlayer insulating layer ILD4 and the second peripheral bonding insulating layer 203 so that the first peripheral circuit 330 of the first peripheral circuit structure PERI1 faces the second substrate 201 and the first peripheral circuit 330 may be face the rear surface of the second substrate 201. In this case, the carrier substrate 50 exposed upwardly may be removed.

Referring to FIG. 10H, a through-via 240 extending into (e.g., penetrating through) the second substrate 201 and electrically connected to the first peripheral interconnection lines 373 and 385 may be formed.

A second peripheral interconnection line 285 electrically connecting the through-via 240 and the second peripheral interconnection lines 273 and 285 may be formed, and second bonding structures 293 and 295 may be formed on the second peripheral interconnection line 285, and then, a second bonding insulating layer CINS2 may be formed on the second peripheral interlayer insulating layer ILD3.

Referring to FIG. 10I, a cell structure CELL may be bonded below the second peripheral circuit structure PERI2. The second peripheral circuit structure PERI2 and the cell structure CELL may be (electrically) connected to each other through the second bonding insulating layer CINS2 and the second bonding structures 293 and 295 of the second peripheral circuit structure PERI2, and the first bonding insulating layer CINS1 and the first bonding structures 193 and 195 of the cell structure CELL.

In order to form the cell structure CELL below a second peripheral circuit structure PERI2, an operation of forming gate electrodes 130, a first channel structure CH extending into (e.g., penetrating through) the gate electrodes 130, a second channel structure SCH (electrically) connected to the first channel structure CH, and cell interconnection lines electrically connected to the channel structures CH and SCH on a base plate 110, an operation of forming first and second cell interlayer insulating layers ILD1 and ILD2 on (e.g., covering or overlapping) the gate electrodes 130, the channel structures CH and SCH and the cell interconnection lines, and an operation of forming first bonding structures 193 and 195 on the cell interconnection lines may be preceded. After forming the cell structure CELL, the first and second peripheral circuit structures PERI1 and PERI2 may be inverted so that the first bonding insulating layer CINS1 of the cell structure CELL faces the second bonding insulating layer CINS2 of the second peripheral circuit structure PERI2.

Referring to FIG. 4, the semiconductor device 100 may be formed by forming the passivation layer 302 and the pad patterns for an input/output connection in an upper portion of the first substrate 301.

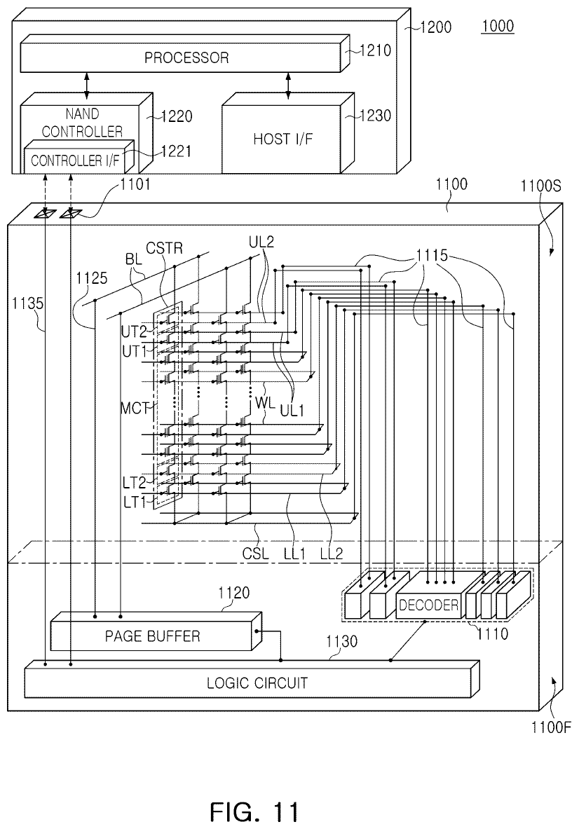

FIG. 11 is a schematic diagram illustrating a data storage system including a semiconductor device according to example embodiments of the present disclosure.

Referring to FIG. 11, a data storage system 1000 may include a semiconductor device 1100 and a controller 1200 electrically connected to the semiconductor device 1100. The data storage system 1000 may be a storage device including one or more semiconductor devices 1100 or an electronic device including the storage device. For example, the data storage system 1000 may be a solid state drive device (SSD), a Universal Serial Bus (USB), a computing system, a medical device, or a communication device, including one or more semiconductor devices 1100.

The semiconductor device 1100 may be a nonvolatile memory device, and may be, for example, a NAND flash memory device as described above with reference to FIGS. 1A, 1B, 1C, 2, 3A, 3B, 3C, 4, 5A, 5B, 5C, 5D, 5E, 6A, 6B, 7A, 7B, 8, 9, 10A, 10B, 10C, 10D, 10E, 10F, 10G, 10H, and 10I. The semiconductor device 1100 may include a first semiconductor structure 1100F and a second semiconductor structure 1100S on the first semiconductor structure 1100F. In example embodiments, the first semiconductor structure 1100F may be disposed next to the second semiconductor structure 1100S. The first semiconductor structure 1100F may be a peripheral circuit structure including the decoder circuit 1110, the page buffer 1120, and the logic circuit 1130. The second semiconductor structure 1100S may be a memory cell structure including the bit line BL, the common source line CSL, the word lines WL, first and second gate upper interconnection lines UL1 and UL2, first and second gate lower interconnection lines LL1 and LL2, and cell strings CSTR between the bit line BL and the common source line CSL.

In the second semiconductor structure 1100S, each cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed according to example embodiments.

In example embodiments, the upper transistors UT1 and UT2 may include string select transistors, and the lower transistors LT1 and LT2 may include ground select transistors. The gate lower interconnection lines LL1 and LL2 may be gate electrodes of the lower transistors LT1 and LT2, respectively. The word lines WL may be gate electrodes of the memory cell transistors MCT, and the gate upper interconnection lines UL1 and UL2 may be gate electrodes of the upper transistors UT1 and UT2, respectively.

In example embodiments, the lower transistors LT1 and LT2 may include a lower erase control transistor LT1 and a ground select transistor LT2 (electrically) serially connected. The upper transistors UT1 and UT2 may include a string select transistor UT1 and an upper erase control transistor UT2 (electrically) serially connected. At least one of the lower erase control transistor LT1 or the upper erase control transistor UT2 may be used for an erase operation of erasing data stored in the memory cell transistors MCT by utilizing the GIDL phenomenon.

The common source line CSL, the first and second gate lower interconnection lines LL1 and LL2, the word lines WL, and the first and second gate upper interconnection lines UL1 and UL2 may be electrically connected to the decoder circuit 1110 through first interconnection lines 1115 extending from the first semiconductor structure 1100F to the second semiconductor structure 1100S. The bit lines BL may be electrically connected to the page buffer 1120 through second interconnection lines 1125 extending from the first semiconductor structure 1100F to the second semiconductor structure 1100S.

In the first semiconductor structure 1100F, the decoder circuit 1110 and the page buffer 1120 may execute a control operation for at least one selected memory cell transistor among a plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output interconnection line 1135 extending from the first semiconductor structure 1100F to the second semiconductor structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware and may control the NAND controller 1220 to access the semiconductor device 1100. The NAND controller 1220 may include a controller interface 1221 processing communication with the semiconductor device 1100. Through the controller interface 1221, control commands for controlling the semiconductor device 1100, data to be written to the memory cell transistors MCT of the semiconductor device 1100, data to be read from the memory cell transistors MCT of the semiconductor device 1100, and the like, may be transmitted. The host interface 1230 may provide a communication function between the data storage system 1000 and an external host. When control commands are received from the external host through the host interface 1230, the processor 1210 may control the semiconductor device 1100 in response to the control command.

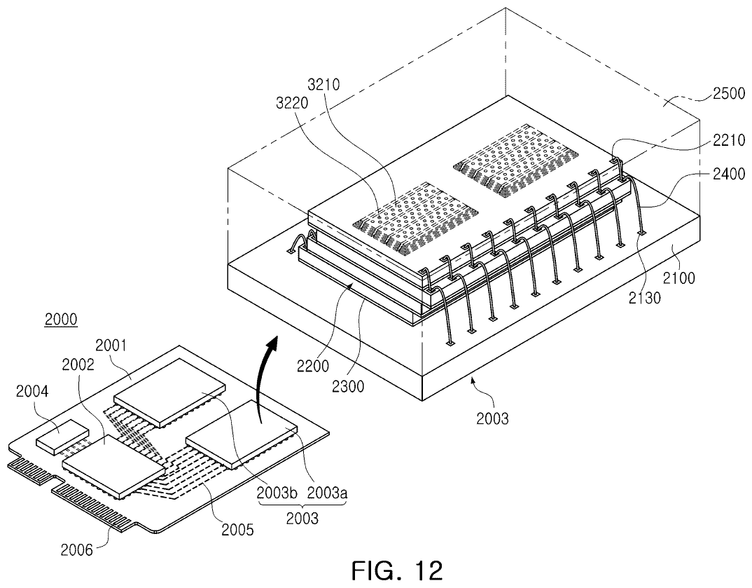

FIG. 12 is a perspective view schematically illustrating a data storage system including a semiconductor device according to example embodiments of the present disclosure.

Referring to FIG. 12, a data storage system 2000 according to an example embodiment of the present disclosure may include a main board 2001, a controller 2002 mounted on the main board 2001, one or more semiconductor packages 2003, and a DRAM 2004. The semiconductor package 2003 and the DRAM 2004 may be (electrically) connected to the controller 2002 by interconnection patterns 2005 formed on the main board 2001.

The main board 2001 may include a connector 2006 including a plurality of pins coupled to the external host. The number and arrangement of the plurality of pins in the connector 2006 may vary depending on a communication interface between the data storage system 2000 and the external host. In example embodiments, the data storage system 2000 may communicate with the external host according to any one of the following interfaces: Universal Serial Bus (USB), Peripheral Component Interconnect Express (PCI-Express), Serial Advanced Technology Attachment (SATA), M-Phy for Universal Flash Storage (UFS). In example embodiments, the data storage system 2000 may operate by power supplied from the external host through the connector 2006. The data storage system 2000 may further include a Power Management Integrated Circuit (PMIC) that distributes power supplied from the external host to the controller 2002 and a semiconductor package 2003.

The controller 2002 may write data to the semiconductor package 2003 or may read data from the semiconductor package 2003, and improve the operating speed of the data storage system 2000.

The DRAM 2004 may be a buffer memory for mitigating a speed difference between the semiconductor package 2003, which is a data storage space, and the external host. The DRAM 2004 included in the data storage system 2000 may also function as a kind of cache memory, and may provide a space for temporarily storing data in a control operation for the semiconductor package 2003. When the DRAM 2004 is included in the data storage system 2000, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of each of the semiconductor chips 2200, a bonding structure 2400 electrically connecting the semiconductor chips 2200 and the package substrate 2100, and a molding layer 2500 on (e.g., covering or overlapping) the semiconductor chips 2200 and the bonding structure 2400 on the package substrate 2100.

The package substrate 2100 may be a printed circuit substrate including package upper pads 2130. Each semiconductor chip 2200 may include an input/output pad 2210. The input/output pad 2210 may correspond to the input/output pad 1101 of FIG. 13. Each of the semiconductor chips 2200 may include gate stack structures 3210 and channel structures 3220. Each of the semiconductor chips 2200 may include the semiconductor device described above with reference to FIGS. FIGS. 1A, 1B, 1C, 2, 3A, 3B, 3C, 4, 5A, 5B, 5C, 5D, 5E, 6A, 6B, 7A, 7B, 8, and 9.

In example embodiments, the bonding structure 2400 may be a bonding wire that electrically connects the input/output pad 2210 and the package upper pads 2130. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. According to example embodiments, in each of the first and second semiconductor packages 2003a and 2003b, the semiconductor chips 2200 may be electrically connected to each other by a bonding structure including a through-silicon via (TSV), instead of a bonding structure 2400 in a bonding wire manner.

In example embodiments, the controller 2002 and the semiconductor chips 2200 may be included in one package. In example embodiments, the controller 2002 and the semiconductor chips 2200 may be mounted on a separate interposer substrate different from the main board 2001, and the controller 2002 and the semiconductor chips 2200 may be connected to each other by interconnection lines formed on the interposer substrate.

The present disclosure is not limited to the above-described embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes should be construed as being included in the scope of the present disclosure.

What is claimed is:

1. A semiconductor device, comprising:
a first peripheral circuit structure that includes a first substrate having a first thickness, a first peripheral circuit including a first gate stack on the first substrate, and first peripheral interconnection lines electrically connected to the first peripheral circuit;
a second peripheral circuit structure that includes a second substrate of a first conductivity type and having a second thickness that is equal to or less than the first thickness, second peripheral circuits each including a second gate stack on a front surface of the second substrate, second peripheral interconnection lines electrically connected to the second peripheral circuits, peripheral bonding pads electrically connected to the second peripheral interconnection lines, and a rear doping layer including impurities of the first conductivity type and is on a rear surface of the second substrate, wherein the rear surface is opposite to the front surface in a vertical direction and faces the first peripheral circuit structure, and wherein the vertical direction is perpendicular to the rear surface and/or the front surface; and
a cell structure including a source structure, gate electrodes on the source structure, channel structures extending into the gate electrodes in the vertical direction, cell interconnection lines electrically connected to the gate electrodes and the channel structures, and cell bonding pads electrically connected to the cell interconnection lines, wherein the cell structure faces the front surface, and wherein the cell bonding pads are in contact with the peripheral bonding pads.

2. The semiconductor device of claim 1,
wherein the first peripheral circuit is configured to operate at an operating voltage of a first voltage, and
wherein the second peripheral circuits are configured to operate at an operating voltage of a second voltage that is greater than the first voltage.

3. The semiconductor device of claim 1,
wherein the first gate stack includes a first gate insulating film having a first dielectric constant, and
wherein the second gate stack includes a second gate insulating film having a second dielectric constant that is lower than the first dielectric constant.

4. The semiconductor device of claim 1,
wherein a thickness of the second substrate in the vertical direction is 2 micrometers (μm) to 6 μm.

5. The semiconductor device of claim 1,
wherein the second peripheral circuit structure includes a well region comprising impurities of a second conductivity type that is different from the first conductivity type in the second substrate,
wherein the second peripheral circuit structure includes a non-well region in the second substrate, and
wherein the non-well region is free of impurities of the second conductivity type or has a concentration of impurities of the second conductivity type less than a concentration of impurities in the well region.

6. The semiconductor device of claim 5,
wherein the second peripheral circuits include:
an enhancement transistor in the non-well region, wherein the enhancement transistor includes first source/drain regions having impurities of the second conductivity type; and
a depletion transistor in the non-well region, wherein the depletion transistor includes second source/drain regions having impurities of the second conductivity type and a first channel region having impurities of the second conductivity type, wherein the first channel region extends between ones of the second source/drain regions.

7. The semiconductor device of claim 6,
wherein the enhancement transistor includes a second channel region having impurities of the first conductivity type,
wherein the second channel region extends between ones of the first source/drain regions,
wherein the depletion transistor further includes a third channel region having impurities of the first conductivity type, and
wherein the third channel region extends between ones of the second source/drain regions.

8. The semiconductor device of claim 7,
wherein the third channel region is on the first channel region.

9. The semiconductor device of claim 6, further comprising:
an element isolation region extending from the front surface of the second substrate into the second substrate between the depletion transistor and the enhancement transistor; and
a body conductive layer on the element isolation region.

10. The semiconductor device of claim 9,
wherein the body conductive layer includes impurities of the first conductivity type.

11. The semiconductor device of claim 9,
wherein the body conductive layer is spaced apart from the rear doping layer in the vertical direction and overlaps the rear doping layer in the vertical direction.

12. The semiconductor device of claim 6,
wherein the depletion transistor is spaced from the well region, and
wherein the depletion transistor is closer to the well region than the enhancement transistor in a horizontal direction that is parallel with the rear surface and/or the front surface.

13. The semiconductor device of claim 6,
wherein the second peripheral circuits include a first conductivity type transistor in the well region,
wherein the first conductivity type transistor includes third source/drain regions having impurities of the first conductivity type, and
wherein the first conductivity type transistor and the depletion transistor comprise a pass circuit.

14. A semiconductor device, comprising:
a first peripheral circuit structure including a first substrate having a first thickness, and first transistors that are configured to operate at an operating voltage of a first voltage;
a second peripheral circuit structure on the first peripheral circuit structure, and including a second substrate of a first conductivity type having a second thickness that is equal to or less than the first thickness, second transistors that are configured to operate at an operating voltage of a second voltage that is greater than the first voltage, on a front surface of the second substrate, and a rear doping layer including impurities of the first conductivity type on a rear surface of the second substrate, wherein the rear surface is opposite to the front surface in a vertical direction that is perpendicular to the rear surface and/or the front surface; and
a cell structure electrically connected to the second peripheral circuit structure, and including gate electrodes and channel structures extending into the gate electrodes in the vertical direction.

15. The semiconductor device of claim 14,
wherein the second peripheral circuit structure includes:
a first well region having impurities of the first conductivity type in the second substrate;
a second well region having impurities of a second conductivity type different from the first conductivity type in the second substrate; and
a non-well region that is free of impurities of the first conductivity type, free of impurities of the second conductivity type, or has a less concentration of impurities of the first conductivity type than the first well region and/or a less concentration of impurities of the second conductivity type than the second well region.

16. The semiconductor device of claim 15,
wherein the second transistors include:
an enhancement transistor in the non-well region, wherein the enhancement transistor includes first source/drain regions having impurities of the second conductivity type;
a depletion transistor in the non-well region, wherein the depletion transistor includes second source/drain regions and a first channel region having impurities of the second conductivity type; and
a first conductivity type transistor in the second well region, wherein the first conductivity type transistor includes third source/drain regions having impurities of the first conductivity type, and
wherein the first conductivity type transistor and the depletion transistor comprise a pass circuit.

17. The semiconductor device of claim 16,
wherein the enhancement transistor includes a second channel region having impurities of the first conductivity type
wherein the second channel region extends between ones of the first source/drain regions,
wherein the depletion transistor further includes a third channel region having impurities of the first conductivity type
wherein the third channel region extends between ones of the second source/drain regions, and
wherein the third channel region is on the first channel region.

18. The semiconductor device of claim 16,
wherein the second peripheral circuit structure further includes:
an element isolation region between the depletion transistor and the enhancement transistor on the front surface of the second substrate in the non-well region; and
a body conductive layer on the element isolation region, and
wherein the body conductive layer includes impurities of the first conductivity type.

19. The semiconductor device of claim 16,
wherein each of the depletion transistor, the enhancement transistor, and the first conductivity type transistor includes a gate stack,
wherein the gate stack includes a second gate insulating film and a gate electrode layer stacked in the vertical direction, and
wherein the second gate insulating film has a dielectric constant less than a dielectric constant of a first gate insulating film of the first transistors.

20. A semiconductor device, comprising:
a first peripheral circuit structure on a first substrate having a first thickness, and including a page buffer and a row decoder configured to operate at an operating voltage of a first voltage;
a second peripheral circuit structure including a second substrate having a front surface and a rear surface, the rear surface facing the first peripheral circuit structure, and having a second thickness, equal to or less than the first thickness, a pass circuit configured to operate at an operating voltage of a second voltage that is greater than the first voltage, and a common source line driver configured to operate at an operating voltage of a third voltage that is greater than the second voltage, and a rear doping layer including impurities of a same conductivity type as the second substrate on the rear surface of the second substrate; and
a cell structure electrically connected to the second peripheral circuit structure, and including a channel structure extending into gate electrodes.
